(19) United States
(12) Patent Application Publication
(10) Pub. No.: US 2026/0253622 A1
(43) Pub. Date: Aug. 27, 2026

(54) SEMICONDUCTOR MEMORY DEVICE AND METHOD FOR MANUFACTURING SEMICONDUCTOR MEMORY DEVICE

(71) Applicant: Kioxia Corporation, Tokyo (JP)

(72) Inventor: Shoya MATSUBARA, Yokkaichi Mie (JP)

(73) Assignee: Kioxia Corporation, Tokyo (JP)

(21) Appl. No.: 19/236,232

(22) Filed: Jun. 12, 2025

(30) Foreign Application Priority Data
Feb. 25, 2025 (JP) 2025-027874

(51) Int. Cl. G11C 5/06; H01L 23/00; H01L 25/18; H10B 41/10; H10B 41/27; H10B 41/40; H10B 43/10; H10B 43/27; H10B 43/40; H10D 62/60; H10D 80/30

(52) U.S. Cl. CPC G11C 5/063; H10B 41/10; H10B 41/27; H10B 41/40; H10B 43/10; H10B 43/27; H10B 43/40; H10D 62/60; H10D 80/30; H10W 72/90; H10W 90/00; H10W 90/792

(57) ABSTRACT

A semiconductor memory device of the embodiment includes a stacked body in which a plurality of first conductive layers and a plurality of first insulating layers are alternately stacked one by one, a pillar extending in the stacked body in a stacking direction of the stacked body and including a semiconductor layer having an upper end protruding from the stacked body, a plate-like portion extending in the stacked body in the staking direction and a first direction intersecting the stacking direction at a position adjacent to the pillar, the plate-like portion including a second conductive layer having an upper end protruding from the stacked body, and a first layer that is disposed above the stacked body, covers the upper end of the semiconductor layer and an upper end of the plate-like portion, and contains a semiconductor as a main component, and the plate-like portion includes a void portion in the upper end thereof.

### CROSS-REFERENCE TO RELATED APPLICATIONS

This application is based upon and claims the benefit of priority from Japanese Patent Application No. 2025-027874, filed on Feb. 25, 2025; the entire contents of which are incorporated herein by reference.

### FIELD

Embodiments described herein relate generally to a semiconductor memory device and a method for manufacturing the semiconductor memory device.

### BACKGROUND

In a semiconductor memory device such as a three-dimensional nonvolatile memory, a pillar penetrating a stacked body in which a plurality of conductive layers and a plurality of insulating layers are alternately stacked is formed. At that time, in order to activate impurities in the source line connected to the upper end of the pillar, laser light or the like may be emitted from above the semiconductor memory device. However, in some cases, impurities in the source line is not sufficiently activated around the pillar adjacent to another member or the like.

### BRIEF DESCRIPTION OF THE DRAWINGS

FIGS. 1A and 1B are diagrams illustrating a schematic configuration example of a semiconductor memory device according to an embodiment;

FIGS. 2A to 2C are cross-sectional views illustrating an example of a configuration of the semiconductor memory device according to the embodiment;

FIGS. 3A to 3C are diagrams sequentially illustrating a part of the procedure of a method for manufacturing the semiconductor memory device according to the embodiment;

FIGS. 4A and 4B are diagrams sequentially illustrating a part of the procedure of the method for manufacturing the semiconductor memory device according to the embodiment;

FIGS. 5A and 5B are diagrams sequentially illustrating a part of the procedure of the method for manufacturing the semiconductor memory device according to the embodiment;

FIGS. 6A and 6B are diagrams sequentially illustrating a part of the procedure of the method for manufacturing the semiconductor memory device according to the embodiment;

FIGS. 7A and 7B are diagrams sequentially illustrating a part of the procedure of the method for manufacturing the semiconductor memory device according to the embodiment;

FIGS. 8A and 8B are diagrams sequentially illustrating a part of the procedure of the method for manufacturing the semiconductor memory device according to the embodiment;

FIGS. 9A and 9B are diagrams sequentially illustrating a part of the procedure of the method for manufacturing the semiconductor memory device according to the embodiment;

FIGS. 10A and 10B are diagrams sequentially illustrating a part of the procedure of the method for manufacturing the semiconductor memory device according to the embodiment;

FIGS. 11A and 11B are diagrams sequentially illustrating a part of the procedure of the method for manufacturing the semiconductor memory device according to the embodiment;

FIGS. 12A and 12B are diagrams sequentially illustrating a part of the procedure of the method for manufacturing the semiconductor memory device according to the embodiment;

FIGS. 13A to 13D are diagrams sequentially illustrating a part of the procedure of the method for manufacturing the semiconductor memory device according to the embodiment;

FIGS. 14A to 14D are diagrams sequentially illustrating a part of the procedure of the method for manufacturing the semiconductor memory device according to the embodiment;

FIGS. 15A to 15D are diagrams illustrating a method of forming a source line of a semiconductor memory device according to a comparative example;

FIGS. 16A and 16B are diagrams sequentially illustrating a part of the procedure of a method for manufacturing a semiconductor memory device according to a first modification of the embodiment;

FIGS. 17A and 17B are diagrams sequentially illustrating a part of the procedure of the method for manufacturing the semiconductor memory device according to the first modification of the embodiment;

FIGS. 18A and 18B are diagrams sequentially illustrating a part of the procedure of the method for manufacturing the semiconductor memory device according to the first modification of the embodiment;

FIGS. 19A to 19D are diagrams illustrating a part of the procedure of the method for manufacturing the semiconductor memory device according to the first modification of the embodiment;

FIGS. 20A and 20B are diagrams sequentially illustrating a part of the procedure of a method for manufacturing a semiconductor memory device according to a second modification of the embodiment;

FIGS. 21A and 21B are diagrams sequentially illustrating a part of the procedure of the method for manufacturing the semiconductor memory device according to the second modification of the embodiment;

FIGS. 22A and 22B are diagrams sequentially illustrating a part of the procedure of the method for manufacturing the semiconductor memory device according to the second modification of the embodiment;

FIG. 23 is a cross-sectional view illustrating a schematic configuration example of a semiconductor memory device according to a third modification of the embodiment;

FIGS. 24A and 24B are diagrams sequentially illustrating a part of the procedure of a method for manufacturing the semiconductor memory device according to the third modification of the embodiment; and

FIGS. 25A and 25B are diagrams sequentially illustrating a part of the procedure of the method for manufacturing the semiconductor memory device according to the third modification of the embodiment.

### DETAILED DESCRIPTION

A semiconductor memory device of the embodiment includes a stacked body in which a plurality of first conductive layers and a plurality of first insulating layers are alternately stacked one by one, a pillar extending in the stacked body in a stacking direction of the stacked body and including a semiconductor layer having an upper end protruding from the stacked body, a plate-like portion extending in the stacked body in the staking direction and a first direction intersecting the stacking direction at a position adjacent to the pillar, the plate-like portion including a second conductive layer having an upper end protruding from the stacked body, and a first layer that is disposed above the stacked body, covers the upper end of the semiconductor layer and an upper end of the plate-like portion, and contains a semiconductor as a main component, and the plate-like portion includes a void portion in the upper end thereof.

Hereinafter, the embodiment of the present invention will be described in detail with reference to the drawings. Note that the present invention is not limited by the following embodiment. In addition, constituent elements in the following embodiment include those that can be easily assumed by those skilled in the art or those that are substantially the same.

### Configuration Example of Semiconductor Memory Device

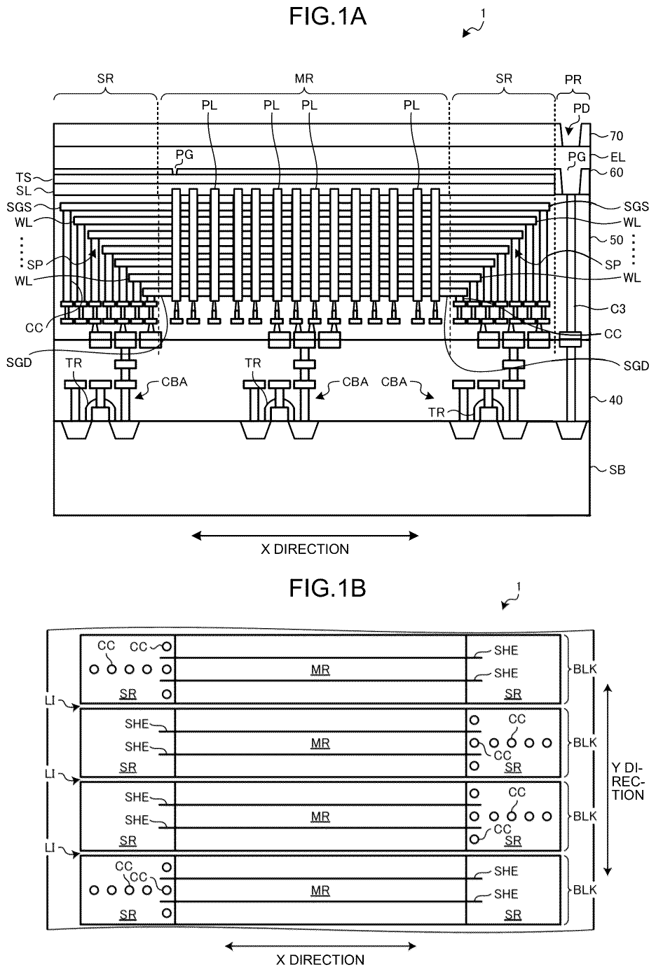

FIGS. 1A and 1B are diagrams illustrating a schematic configuration example of a semiconductor memory device 1 according to the embodiment. More specifically, FIG. 1A is a cross-sectional view of the semiconductor memory device 1 along the X direction, and FIG. 1B is a schematic plan view illustrating a layout of the semiconductor memory device 1.

However, in FIG. 1A, hatching is omitted in consideration of visibility of the drawing. In addition, in FIG. 1A, configurations that do not necessarily exist in the same cross section are illustrated, and some upper layer wirings and the like are omitted.

In addition, in the present specification, both the X direction and the Y direction are directions along the direction of the surface of the word line WL, and the X direction and the Y direction are orthogonal to each other. In addition, the electrical extraction direction of the word line WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIG. 1A, the semiconductor memory device 1 includes a semiconductor substrate SB, a peripheral circuit CBA, one or more select gate lines SGD, a plurality of word lines WL, one or more select gate lines SGS, a source line SL, an electrode film EL, and the like in this order from the lower side of the drawing.

In the present specification, the side on which the source line SL is disposed with respect to the plurality of word lines WL and the select gate lines SGD and SGS is defined as the upper side of the semiconductor memory device 1. That is, the source side of the semiconductor memory device 1 is the upper side, and the drain side is the lower side.

The semiconductor substrate SB is, for example, a silicon substrate or the like. The peripheral circuit CBA including a transistor TR, wiring, and the like is disposed on the surface of the semiconductor substrate SB, and the entire surface is covered by an insulating layer 40. Above the semiconductor substrate SB on which the peripheral circuit CBA and the like are disposed, a plurality of word lines WL and select gate lines SGD and SGS entirely covered with an insulating layer 50 are disposed.

As illustrated in FIGS. 1A and 1B, a memory region MR is disposed at the center in the X direction of the plurality of word lines WL and the like, and a stepped region SR is disposed at both ends in the X direction of the plurality of word lines WL and the like. The memory region MR and the stepped regions SR are divided into a plurality of regions by a plurality of plate-like contacts LI penetrating through a plurality of word lines WL and the like and extending in the direction along the X direction.

Note that a region disposed between the plate-like contacts LI adjacent in the Y direction and including the memory region MR and the stepped region SR is referred to as a block region BLK. As described below, the memory region MR includes a plurality of memory cells that hold data in a nonvolatile manner, and the block region BLK is an erase unit of the data.

In addition, between the plate-like contacts LI adjacent in the Y direction, a plurality of separation layers SHE penetrating through the select gate line SGD and extending in the direction along the X direction is disposed. The plurality of separation layers SHE extends in the direction along the X direction over the entire memory region MR and reaches a part of the stepped regions SR at both ends in the X direction.

In the memory region MR, a plurality of pillars PL are arranged. The plurality of pillars PL penetrate the plurality of word lines WL and the select gate lines SGD and SGS, and one end thereof protrudes into the source line SL.

A metal layer TS is disposed further above the source line SL. The electrode film EL is disposed above the metal layer TS via an insulating layer 60. The entire electrode film EL is covered with an insulating layer 70 except for a pad region PD provided in a peripheral region PR located on the outer side in the X direction such as the word line WL. The insulating layer 70 has a configuration in which, for example, a silicon oxide layer, a silicon nitride layer, a polyimide layer, and the like are stacked from the lower layer side.

The electrode film EL is connected to the source line SL, a through contact C3, and the like by a plug PG or the like penetrating the insulating layer 60. The through contact C3 is provided in the peripheral region PR, penetrates the insulating layer 50 covering the word lines WL and the like and the insulating layer 40 covering the peripheral circuit CBA, and is connected to the semiconductor substrate SB on which the peripheral circuit CBA is disposed.

From the outside of the semiconductor memory device 1, the semiconductor substrate SB is controlled to a predetermined potential via the pad region PD and the through contact C3. In addition, power and signals from the outside are supplied from the pad region PD to the semiconductor memory device 1.

A plurality of memory cells are formed at intersections of the pillars PL and the word lines WL. As a result, the semiconductor memory device 1 is configured as, for example, a three-dimensional nonvolatile memory in which memory cells are three-dimensionally arranged in the memory region MR.

In the stepped region SR, a stepped portion SP in which a plurality of word lines WL and select gate lines SGD and SGS are processed to form in a stepped shape and terminated is arranged. The separation layer SHE extends from the memory region MR to a portion where the select gate line SGD of the stepped region SR is processed to form in a stepped shape. As a result, in one block region BLK, select gate line SGD is separated into a plurality of regions. In other words, the separation layer SHE penetrates portions below the plurality of word lines WL, so that these portions are partitioned into patterns of the plurality of select gate lines SGD.

A contact CC extending upward in the insulating layer 50 and connected to the word line WL and the select gate lines SGD and SGS of each layer is arranged in a terrace portion of each step including the plurality of word lines WL and the select gate lines SGD and SGS.

In the word line WL and the select gate line SGS, one contact CC is connected for each layer. In the select gate line SGD, one contact CC is connected for each section separated by the separation layer SHE per layer.

Here, in one block region BLK, the plurality of contacts CC are arranged on one side of the stepped regions SR on both sides in the X direction. When viewed on one side in the X direction, for example, a plurality of contacts CC is arranged every two of the block regions BLK.

That is, in the example of FIG. 1B, in the uppermost block region BLK in the drawing, a plurality of contacts CC are arranged, for example, in the stepped region SR on the left side in the drawing out of the stepped regions SR at both end portions in the X direction. In addition, in the block region BLK one below and two below the block region BLK, a plurality of contacts CC is arranged in the stepped region SR on the right side of the drawing out of the stepped regions SR at both ends in the X direction. Furthermore, in the lowermost block region BLK in the drawing, a plurality of contacts CC is arranged again in the stepped region SR on the left side in the drawing.

Therefore, the contacts CC of the stepped regions SR at both ends in the X direction illustrated in FIG. 1A belong to different block regions BLK, and are not actually located in the same cross section.

The word lines WL and the like stacked in multiple layers are individually extracted by these contacts CC. More specifically, from these contacts CC, a write voltage, a read voltage, and the like are applied to a memory cell included in the memory region MR at the center of the plurality of word lines WL via the word line WL at the same height position as the memory cell.

Note that the semiconductor memory device 1 of the embodiment is configured by bonding the insulating layer 40 covering the peripheral circuit CBA and the insulating layer 50 covering the word line WL and the like to each other. In this manner, the insulating layers 40 and 50 function as bonding layers. Further, by bonding the insulating layers 40 and 50, the electrode pads arranged on the surfaces of the insulating layers 40 and 50 are connected to each other, so that the peripheral circuit CBA is electrically connected to the contact CC, the plurality of word lines WL, the select gate lines SGS and SGD, and the pillars PL.

The application of the predetermined voltage from the contact CC to the memory cell is controlled by the peripheral circuit CBA electrically connected to these configurations. In this manner, the peripheral circuit CBA controls the electrical operation of the memory cell.

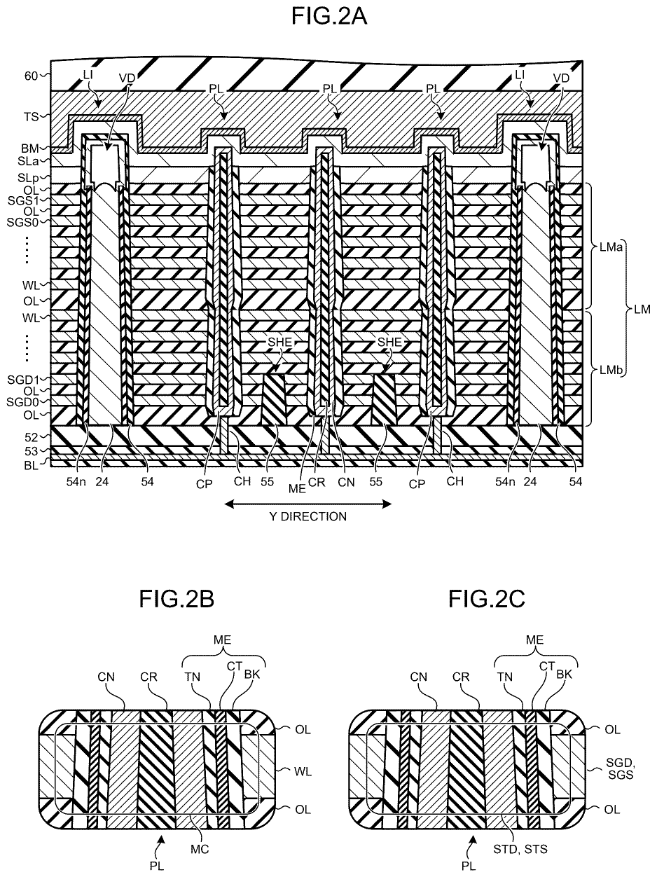

Next, a detailed configuration example of the semiconductor memory device 1 will be described with reference to FIGS. 2A to 2C. FIG. 2 is a cross-sectional view illustrating a configuration example of the semiconductor memory device 1 according to the embodiment.

More specifically, FIG. 2A is a cross-sectional view along the Y direction of the memory region MR of the semiconductor memory device 1. In FIG. 2A, structures above the insulating layer 60 and below the insulating layer 52 to be described later are omitted.

FIG. 2B is an enlarged cross-sectional view of the pillar PL at the height position of the word line WL. FIG. 2C is an enlarged cross-sectional view of the pillar PL at the height positions of the select gate lines SGD and SGS.

As illustrated in FIG. 2A, below the insulating layer 60, a metal layer TS, a barrier metal layer BM, and source lines SLa and SLp are disposed in this order from the insulating layer 60 side.

The insulating layer 60 is, for example, a silicon oxide layer or the like. The metal layer TS is, for example, a tungsten layer or the like, and functions as a source line metal of the semiconductor memory device 1 in addition to the lower source lines SLa and SLp. The barrier metal layer BM is, for example, at least one of a titanium layer, a titanium nitride layer, a tantalum layer, or a tantalum nitride layer, and suppresses diffusion of tungsten atoms from the metal layer TS to a nearby configuration.

The source lines SLa and SLp are, for example, polycrystalline semiconductor layers such as polysilicon layers, and are doped with N-type impurities containing at least one of arsenic and phosphorus. The source line SLp has a function as a source line and a function as a stopper layer at the time of forming the pillar PL in a manufacturing process of the semiconductor memory device 1 to be described later.

A stacked body LM in which a plurality of word lines WL and a plurality of insulating layers OL are alternately stacked one by one is disposed below the source line SLp. The stacked body LM includes a stacked body LMa disposed below the source line SLp and a stacked body LMb disposed further below the stacked body LMa.

The stacked body LMa includes select gate lines SGS1 and SGS0 in order from the source line SLp side on a further upper layer of the uppermost word line WL. These select gate lines SGS1 and SGS0 are source-side select gate lines.

The stacked body LMb includes select gate lines SGD1 and SGD0 further below the lowermost word line WL in order from the lowermost word line WL side. These select gate lines SGD1 and SGD0 are drain-side select gate lines.

However, the number of layers of the word lines WL and the select gate lines SGS and SGD included in the stacked body LM is arbitrary. Therefore, the stacked body LM may include one or three or more select gate lines SGS and SGD. The plurality of word lines WL and the select gate lines SGS and SGD are, for example, tungsten layers or molybdenum layers, and the plurality of insulating layers OL is, for example, silicon oxide layers.

Insulating layers 52 and 53 are disposed below the stacked body LM in order from the stacked body LM side. These insulating layers 52 and 53 constitute a part of the above-described insulating layer 50 (see FIG. 1A).

As described above, the plurality of plate-like contacts LI extend in the stacking direction of the stacked body LM and the direction along the X direction. More specifically, the plate-like contacts LI penetrate the stacked body LM and the source line SLp. The source line SLa above the source line SLp covers the upper ends of the plate-like contacts LI extending above the source line SLp with a substantially equal thickness. As a result, the upper surface of the source line SLa may have irregularities along the shape of the upper ends of the plate-like contacts LI.

Each of these plate-like contacts LI includes a conductive layer 24 such as a tungsten layer and insulating layers 54n and 54 sequentially covering side walls of the conductive layer 24 from the side of the conductive layer 24. The insulating layer 54 also covers the upper end of the conductive layer 24 protruding into the source line SLa. In addition, the conductive layer 24, which is disposed to be sandwiched between the insulating layers 54n and 54 and serves as a core material of the plate-like contact LI, includes a void portion VD in the upper end thereof. In other words, the side walls and the upper surface of the void portion VD at the upper end of the plate-like contact LI are covered with the conductive layer 24 and the insulating layer 54 in this order.

The insulating layer 54 is, for example, a silicon oxide layer or the like. The insulating layer 54n is an insulating layer containing a material different from that of the insulating layer 54, and has etching selectivity with respect to the insulating layer 54. As an example, the insulating layer 54n is a silicon nitride layer or the like. The conductive layer 24 is, for example, a tungsten layer or the like.

In addition, the plate-like contact LI has, for example, a tapered shape in which the width in the Y direction increases from the upper end toward the lower end. Alternatively, the plate-like contact LI has, for example, a bowing shape in which the width in the Y direction is maximized at a predetermined position between the upper end and the lower end.

Among the plurality of plate-like contacts LI, between the plate-like contacts LI adjacent in the Y direction, one or more separation layers SHE extend in the direction along the X direction in the lower layer of the stacked body LM. In the example of FIG. 2A, the separation layer SHE penetrates the select gate lines SGD0 and SGD1 described above and reaches the insulating layer OL adjacent to the select gate line SGD1 in the stacking direction. As a result, the select gate lines SGD0 and SGD1 are divided into a plurality of sections.

In addition, between the plate-like contacts LI adjacent in the Y direction, the plurality of pillars PL extends in the stacked body LM in the stacking direction of the stacked body LM. More specifically, these pillars PL extend in the stacked body LM in the stacking direction of the stacked body LM from the inside of the lowermost insulating layer OL of the stacked body LM, and penetrate the stacked body LM and the source line SLp. As a result, the channel layer CN of the channel layer CN and the memory layer ME described later constituting the pillar PL protrudes above the source line SLp.

The source line SLa above the source line SLp covers the upper end of the channel layer CN, which is a part of the pillar PL extending above the source line SLp, with a substantially equal thickness. As a result, the upper surface of the source line SLa may have irregularities along the shape of the upper end of the channel layer CN of the pillar PL.

The barrier metal layer BM disposed further above the source line SLa also extends along the upper end of the channel layer CN of the plate-like contact LI and the pillar PL described above via the source line SLa.

The plurality of pillars PL takes, for example, a staggered periodic arrangement when viewed from the stacking direction of the stacked body LM. Each pillar PL has, for example, a circular shape, an elliptical shape, a shape like a former Japanese oval gold coin (oval shape), or the like as a cross-sectional shape in a direction along the layer direction of the stacked body LM, that is, in a direction along the XY plane.

In addition, the pillar PL has a tapered shape in which the diameter and the cross-sectional area increase from the upper layer side toward the lower layer side in a portion penetrating the stacked body LMa and a portion penetrating the stacked body LMb, respectively. Alternatively, the pillar PL has a bowing shape in which the diameter and the cross-sectional area are maximized at a predetermined position between the upper layer side and the lower layer side, for example, in the portion penetrating the stacked body LMa and the portion penetrating the stacked body LMb.

In addition, the pillar PL includes a core layer CR serving as a core material, a channel layer CN covering side walls of the core layer CR, a memory layer ME covering side walls of the channel layer CN, and a cap layer CP disposed at a lower end of the pillar PL.

Among the core layer CR, the channel layer CN, and the memory layer ME, the memory layer ME penetrates the stacked body LM and the source line SLp. In addition, the core layer CR and the channel layer CN penetrate the stacked body LM and the source line SLp, and the upper end portion protrudes into the source line SLa.

That is, the portion of the channel layer CN protruding into the source line SLa is not covered with the memory layer ME, and the channel layer CN is in direct contact with the source line SLa. As a result, the channel layer CN is electrically connected to the metal layer TS via the source line SLa.

The cap layer CP disposed at the lower end of the pillar PL connects the channel layer CN and the plug CH extending by penetrating through the lowermost insulating layer OL of the stacked body LM and the insulating layer 52 thereunder. The plug CH connects the bit line BL disposed in the insulating layer 53 and the pillar PL disposed in the stacked body LM. The bit line BL extends below the stacked body LM in the direction along the Y direction so as to intersect with the extraction direction of the word lines WL.

As illustrated in FIGS. 2B and 2C, the memory layer ME has a stacking structure including a block insulating layer BK, a carrier stored layer CT, and a tunnel insulating layer TN in this order from the outer peripheral side of the pillar PL. The carrier stored layer CT of the memory layer ME is, for example, a silicon nitride layer or the like. The block insulating layer BK and the tunnel insulating layer TN of the memory layer ME, and the core layer CR are, for example, silicon oxide layers. The channel layer CN and the cap layer CP are, for example, polycrystalline semiconductor layers such as polysilicon layers.

At least a portion of the channel layer CN protruding into the source line SLa may contain N-type impurities of the same type as the impurities doped in the source lines SLp and SLa, such as arsenic or phosphorus.

As illustrated in FIG. 2B, with the above configuration, memory cells MC are formed in portions facing the respective word lines WL on the side surfaces of the pillars PL. By being applied with a predetermined voltage from the word line WL, data is written to and read from the memory cell MC.

As illustrated in FIG. 2C, select gates STD are formed in portions where the side surfaces of the pillars PL face the select gate lines SGD0 and SGD1. In addition, select gates STS are formed in each of portions where the side surfaces of the pillars PL face the select gate lines SGS0 and SGS1 below the word line WL.

By being applied with a predetermined voltage from each of the select gate lines SGD and SGS, the select gates STD and STS are turned on or off, and the memory cells MC in the pillars PL to which the select gates STD and STS belong are brought into a selected state or a non-selected state.

### Method for Manufacturing Semiconductor Memory Device

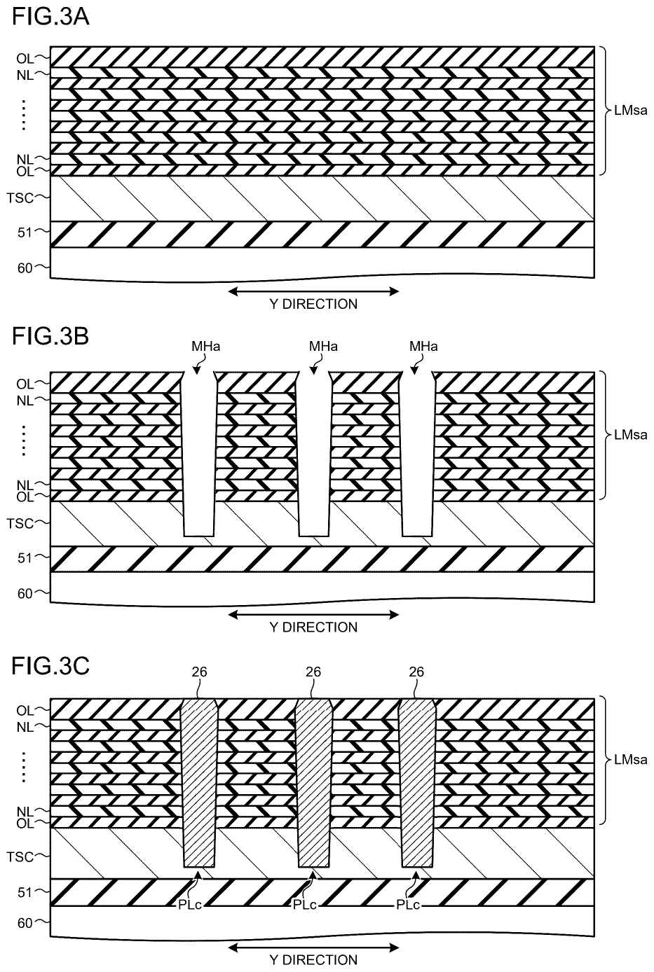

Next, a method for manufacturing the semiconductor memory device 1 according to the embodiment will be described with reference to FIGS. 3A to 14D. FIGS. 3A to 14D are diagrams sequentially illustrating a part of the procedure of a method for manufacturing the semiconductor memory device 1 according to the embodiment. More specifically, FIGS. 3A to 14D illustrate a cross section along the Y direction of a region to be the memory region MR later.

Note that, in the following description, a direction in which a surface of a support substrate SS or a semiconductor substrate SB to be described later on a side on which various types of processing are performed faces is defined as an upper side of the semiconductor memory device 1 in the middle of manufacturing. In other words, the upper side of the drawing of the following drawings is the upper side of the semiconductor memory device 1 in the middle of manufacturing, and the lower side of the drawing is the lower side of the semiconductor memory device 1 in the middle of manufacturing.

As illustrated in FIG. 3A, the support substrate SS is prepared. As the support substrate SS, a semiconductor substrate such as a silicon substrate, an insulating substrate such as a ceramic substrate, a conductive substrate, or the like can be used.

Hereinafter, the configuration to be the source line SL later, the stacked body LM, the pillars PL, and the like are formed on the upper surface of the support substrate SS, and these formation steps are performed in a state where the vertical direction is inverted from the examples of FIGS. 1A to 2C described above.

First, an insulating layer 51 and a semiconductor layer TSC are formed in this order on the support substrate SS. The semiconductor layer TSC is a polycrystalline semiconductor layer or the like such as a non-doped polysilicon layer, and is a layer in which a part becomes the source line SLp later.

In addition, on the semiconductor layer TSC, a stacked body LMsa in which a plurality of insulating layers NL and a plurality of insulating layers OL are alternately stacked one by one is formed. The insulating layer NL is, for example, a silicon nitride layer or the like, and functions as a sacrificial layer that is later replaced with a conductive material and becomes the word line WL or the select gate line SGS.

Thereafter, although not illustrated, the insulating layer NL and the insulating layer OL are processed to form in a stepped shape in a partial region of the stacked body LMsa. Such processing can be performed by repeating the slimming of the mask pattern such as the photoresist layer and the etching of the insulating layer NL and the insulating layer OL of the stacked body LMsa a plurality of times.

That is, a mask pattern is formed on the upper surface of the stacked body LMsa, and the exposed insulating layer NL and the insulating layer OL are etched away one by one. In addition, by processing with oxygen plasma or the like, the end of the mask pattern is retracted to newly expose the upper surface of the stacked body LMsa, and the insulating layer NL and the insulating layer OL are further etched away one by one. By repeating such processing a plurality of times, the stacked body LMsa having a stepped shape at both ends in the X direction is formed.

Thereafter, the stepped shape at both ends in the X direction is covered with a part of the above-described insulating layer 50 (see FIG. 1A).

As illustrated in FIG. 3B, a plurality of memory holes MHa extending in the stacking direction of the stacked body LMsa is formed. At this time, the semiconductor layer TSC below the stacked body LMsa functions as a stopper layer. Therefore, the plurality of memory holes MHa penetrates the stacked body LMsa and reaches a predetermined depth of the semiconductor layer TSC. These memory holes MHa are portions that later penetrate the stacked body LMa of the pillar PL.

As illustrated in FIG. 3C, the memory holes MHa are filled with a sacrificial layer 26 such as a CVD-carbon layer. As a result, a pillar PLc in which the plurality of memory holes MHa is filled with the sacrificial layer 26 is formed.

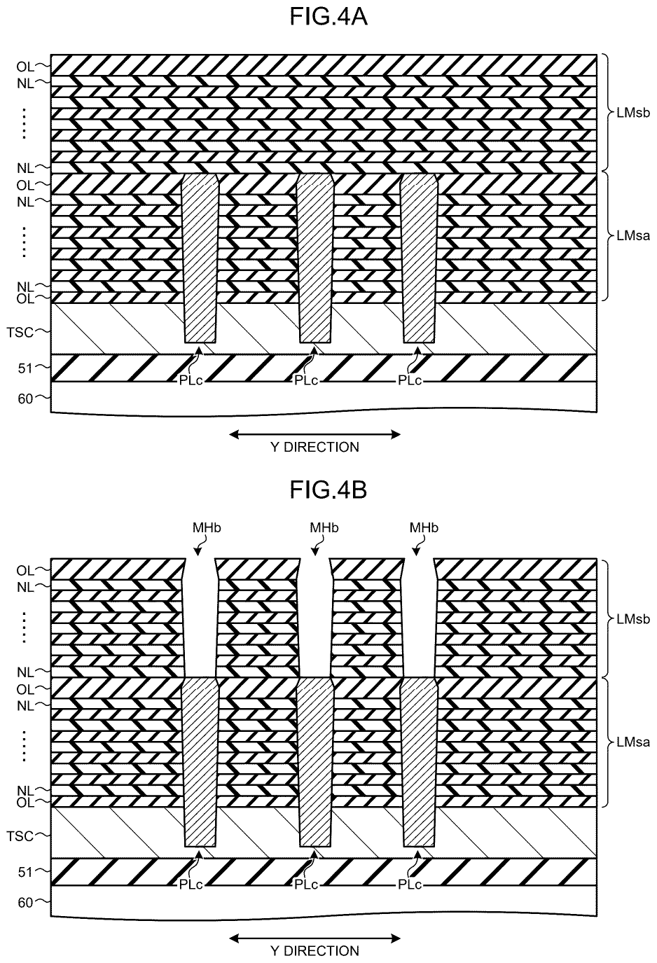

As illustrated in FIG. 4A, a stacked body LMsb covering the stacked body LMsa is formed, and in the stacked body LMsb, the plurality of insulating layers NL and the plurality of insulating layers OL are alternately stacked one by one. The insulating layer NL of the stacked body LMsb functions as a sacrificial layer that is later replaced with a conductive layer and becomes the word line WL or the select gate line SGD.

Thereafter, although not illustrated, the insulating layer NL and the insulating layer OL are processed to form in a stepped shape in a partial region of the stacked body LMsb. Such processing can be performed, similarly to the processing for the stacked body LMsa described above, by repeating the slimming of the mask pattern such as the photoresist layer and the etching of the insulating layer NL and the insulating layer OL of the stacked body LMsb a plurality of times.

At this time, the uppermost step of the stepped portion formed in the stacked body LMsa and the lowermost step of the stepped portion formed in the stacked body LMsb are brought close to each other to form a stepped shape continuously from the lower layer side of the stacked body LMsa to the upper layer side of the stacked body LMsb. As a result, the stacked bodies LMsa and LMsb in which the stepped region SR having a stepped shape is formed at both ends in the X direction from the stacked body LMsa to the stacked body LMsb are formed.

Thereafter, the stepped shape at both ends in the X direction is further covered with a part of the above-described insulating layer 50 (see FIG. 1A).

As illustrated in FIG. 4B, a plurality of memory holes MHb penetrating the stacked body LMsb and connected to the plurality of pillars PLc formed in the stacked body LMsa are formed. The memory holes MHb are portions that later penetrate the stacked body LMb of the pillar PL.

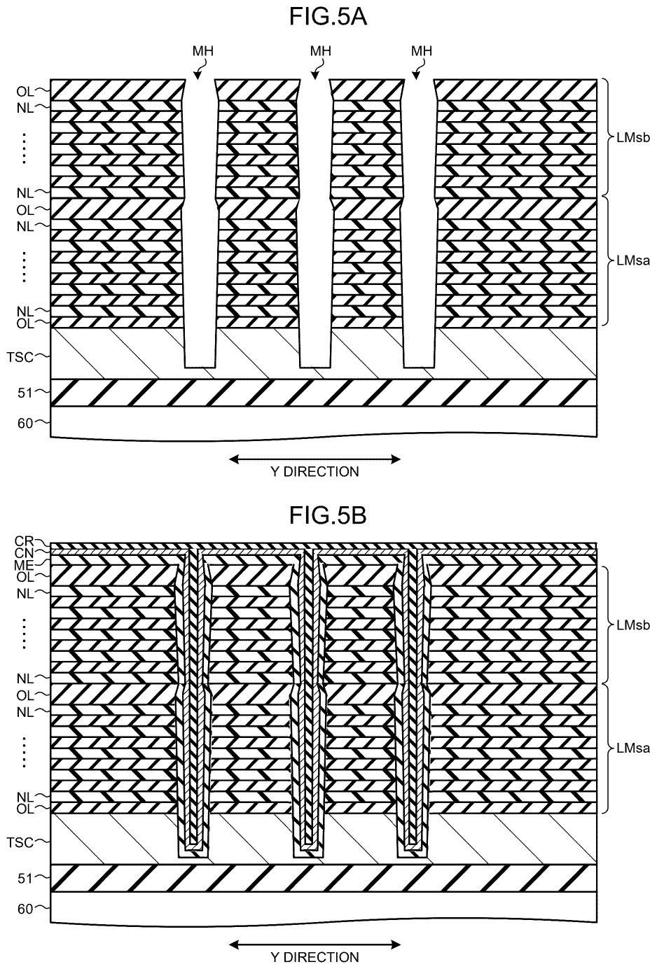

As illustrated in FIG. 5A, the sacrificial layer 26 is removed from the pillar PLc at the bottom of the memory hole MHb. As a result, the memory holes MHa are opened at the bottoms of the plurality of memory holes MHb and penetrate the stacked bodies LMsb and LMsa, and a plurality of memory holes MH reaching the predetermined depth of the source line SL are formed.

Note that, in a case where the sacrificial layer 26 filled in the pillars PLc is a CVD-carbon layer or the like, the sacrificial layer 26 can be collectively removed from these pillars PLc when a mask pattern or the like used at the time of forming the memory hole MHb in FIG. 4B described above is removed by ashing or the like using oxygen plasma.

As illustrated in FIG. 5B, a memory layer ME including a block insulating layer BK, a carrier stored layer CT, and a tunnel insulating layer TN (see FIGS. 2B and 2C) in this order from the side wall side of the memory hole MH is formed on the side wall and the bottom surface of the memory hole MH. The memory layer ME is also formed on the upper surface of the stacked body LMsb.

In addition, a channel layer CN and the core layer CR are formed in this order in the memory hole MH via the memory layer ME. As a result, the channel layer CN is formed on the memory layer ME covering the side surface and the bottom surface of the memory hole MH, and the core layer CR is filled in the central portion of the memory hole MH. The channel layer CN and the core layer CR are also formed in this order on the upper surface of the stacked body LMsb via the memory layer ME.

The channel layer CN is not doped with impurities at this point, and may be in an amorphous state such as an amorphous silicon layer.

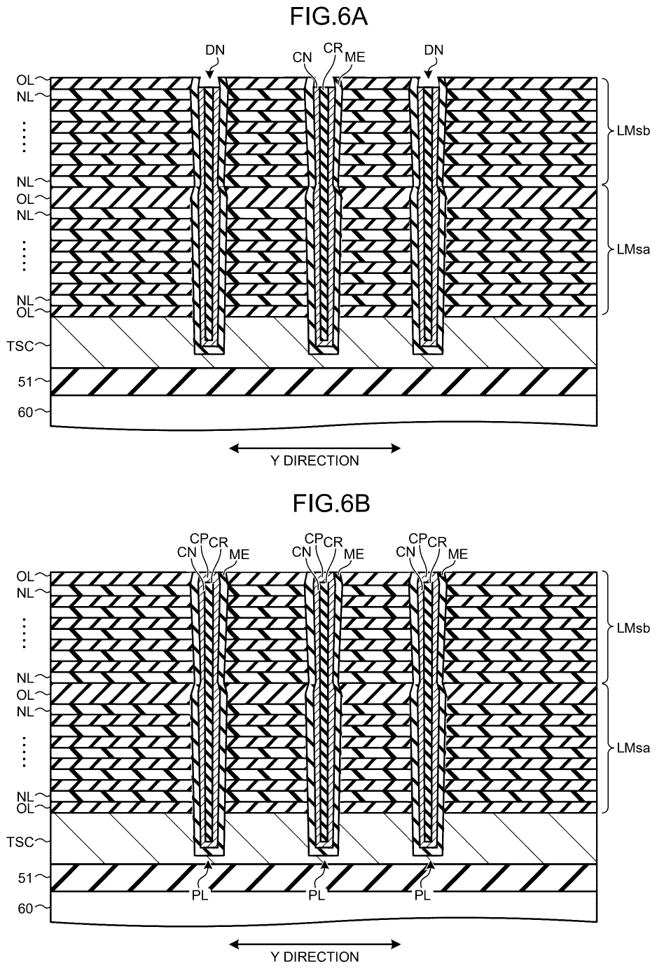

As illustrated in FIG. 6A, the core layer CR, the channel layer CN, and the memory layer ME formed on the upper surface of the stacked body LMsb are etched back and removed together with a part of the insulating layer OL as the uppermost layer of the stacked body LMsb, and the core layer CR is retracted to a predetermined depth of the memory hole MH to form a recess DN at the upper end of the memory hole MH.

As illustrated in FIG. 6B, the cap layer CP is formed in the recess DN at the upper end of the memory hole MH. At this point, the cap layer CP may be in an amorphous state such as an amorphous silicon layer.

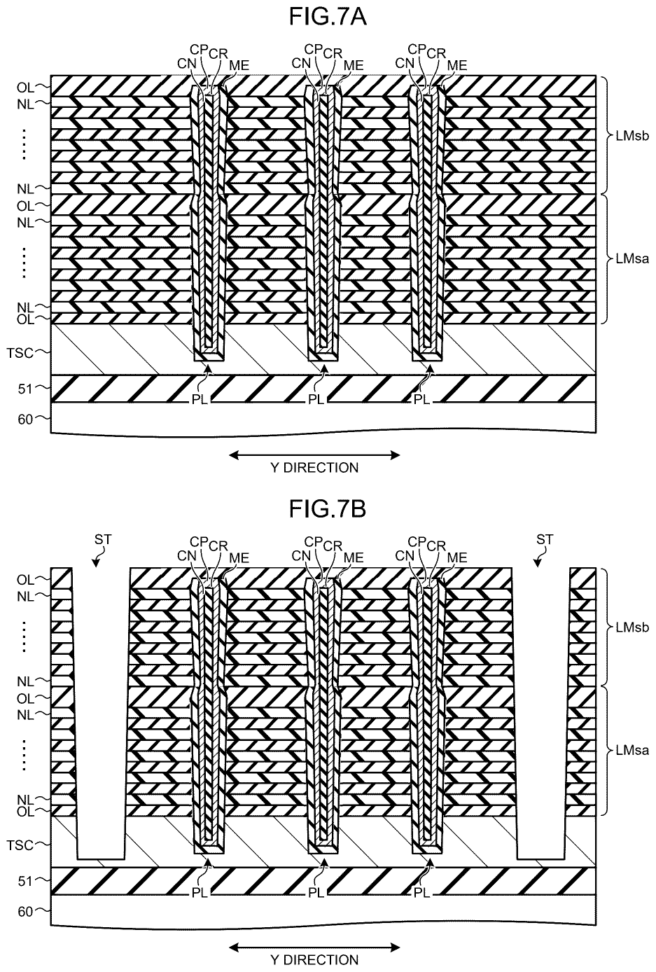

As illustrated in FIG. 7A, by etching back the core layer CR, the channel layer CN, the memory layer ME, and the like formed on the upper surface of the stacked body LMsb, the uppermost insulating layer OL of the stacked body LMb whose film has been thinned is stacked up. As a result, the pillar PL in which the upper end is buried in the uppermost insulating layer OL in the stacked body LMsb is formed. However, at this point, the memory layer ME covers the channel layer CN at the lower end of the pillar PL.

As illustrated in FIG. 7B, a slit ST that penetrates the stacked bodies LMsb and LMsa and reaches a predetermined depth of the semiconductor layer TSC is formed. The slit ST also extends in the direction along the X direction in the stacked bodies LMsa and LMsb.

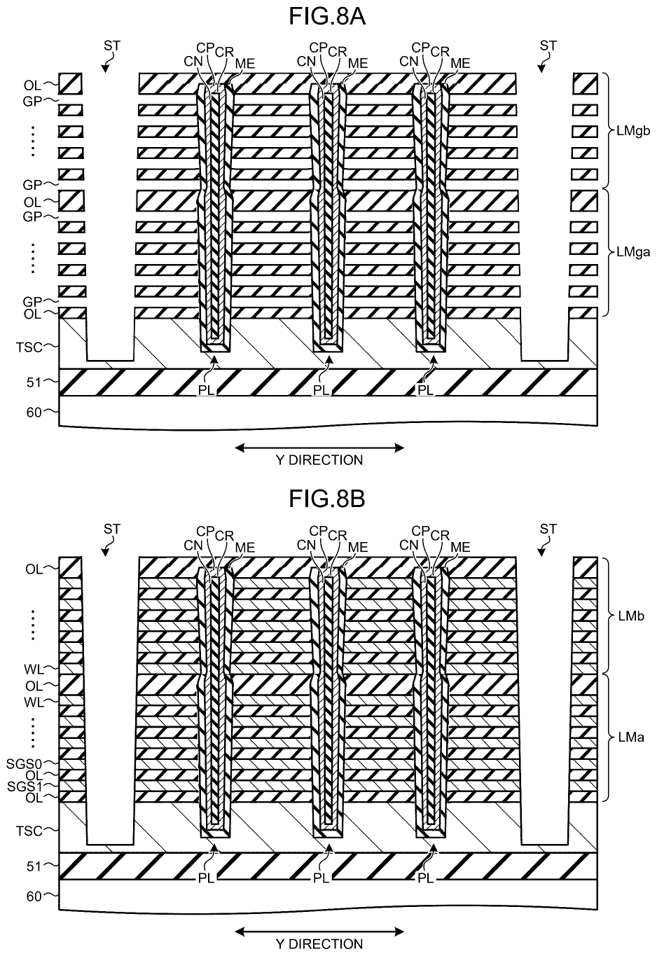

As illustrated in FIG. 8A, a removal liquid of the insulating layer NL such as thermal phosphoric acid is caused to flow from the slit ST into the stacked bodies LMsa and LMsb, and the insulating layers NL of the stacked bodies LMsa and LMsb are removed. As a result, stacked bodies LMga and LMgb having a plurality of gap layers GP from which the insulating layers NL between the insulating layers OL are removed are formed.

The stacked bodies LMga and LMgb including the plurality of gap layers GP have a fragile structure. The plurality of pillars PL support such fragile stacked bodies LMga and LMgb. As a result, bending of the insulating layer OL remaining in the stacked bodies LMga and LMgb and distortion or collapse of the stacked bodies LMga and LMgb are suppressed.

As illustrated in FIG. 8B, a source gas of a conductive material such as tungsten or molybdenum is injected from the slit ST into the stacked bodies LMga and LMgb, and the gap layers GP of the stacked bodies LMga and LMgb are filled with the conductive material to form the plurality of word lines WL and the like. As a result, the stacked body LM including the stacked bodies LMa and LMb in which the plurality of word lines WL and the like and the plurality of insulating layers OL are alternately stacked one by one is formed.

As described above, the process of forming the word line WL from the insulating layer NL is also referred to as a replacement process.

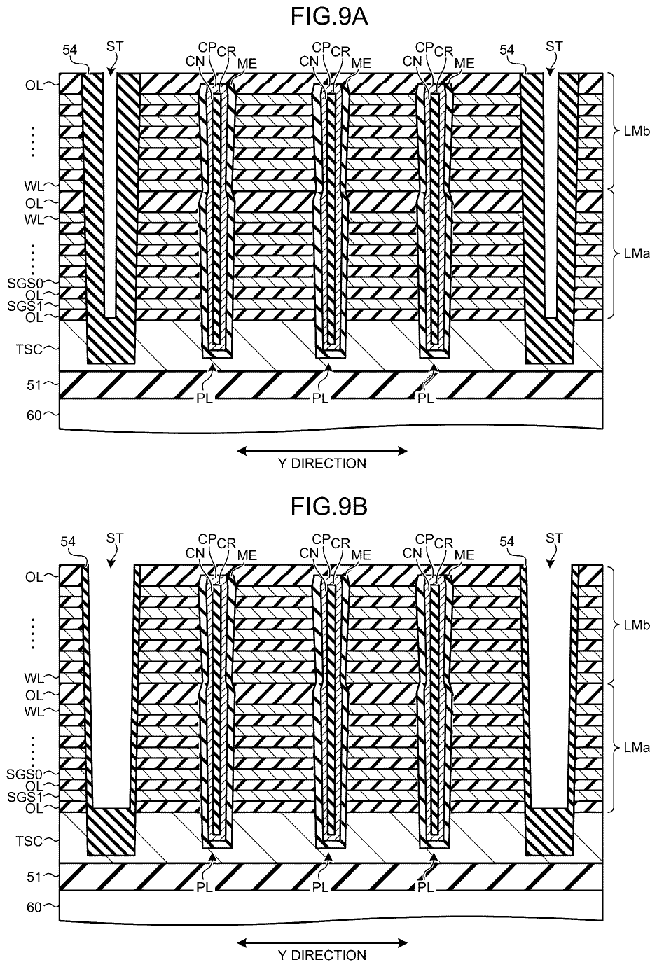

As illustrated in FIG. 9A, the insulating layer 54 covering the side walls and the bottom surface of the slit ST is formed. At this time, the insulating layer 54 is formed to be thicker than the insulating layer 54 to be finally included in the semiconductor memory device 1.

As illustrated in FIG. 9B, the thickness of the insulating layer 54 covering the side walls of the slit ST is reduced to a predetermined thickness. Such processing can be performed by, for example, dry etching using isotropic conditions. As a result, the insulating layer 54 in which the portion covering the bottom surface of the slit ST is thickened is formed. At this time, the upper surface of the insulating layer 54 on the bottom surface of the slit ST is preferably located at least below the height position of the word line WL of the lowermost layer in the subsequent stacked body LMa, and the insulating layer 54 on the bottom surface of the slit ST preferably has a thickness that reaches, for example, the lower surface of the stacked body LMsa.

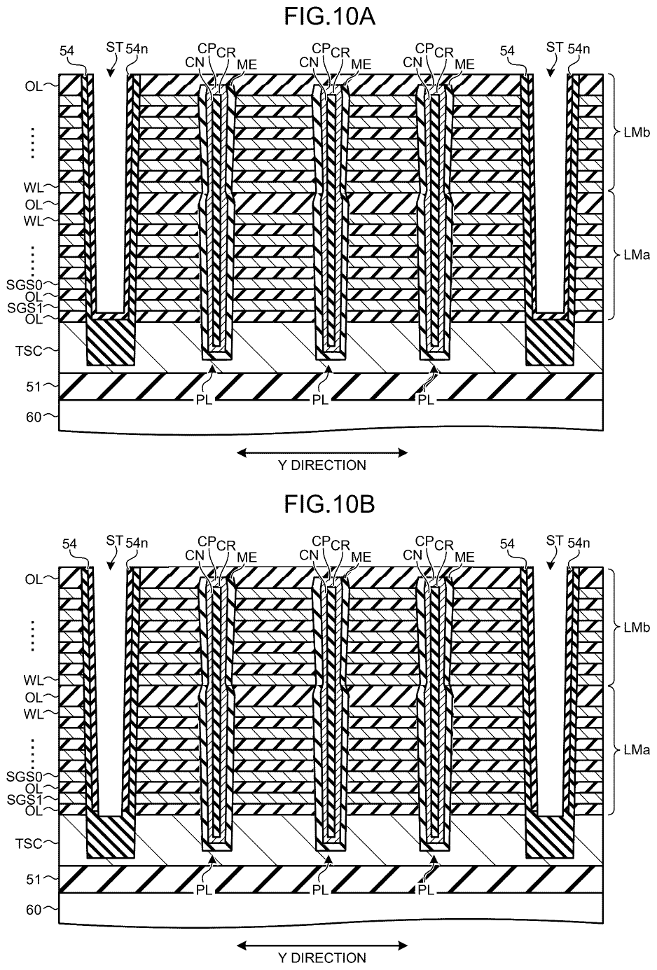

As illustrated in FIG. 10A, the insulating layer 54n covering the side walls and the bottom surface of the slit ST is formed via the insulating layer 54.

As illustrated in FIG. 10B, the insulating layer 54n on the bottom surface of the slit ST is removed by dry etching or the like to partially expose the insulating layer 54.

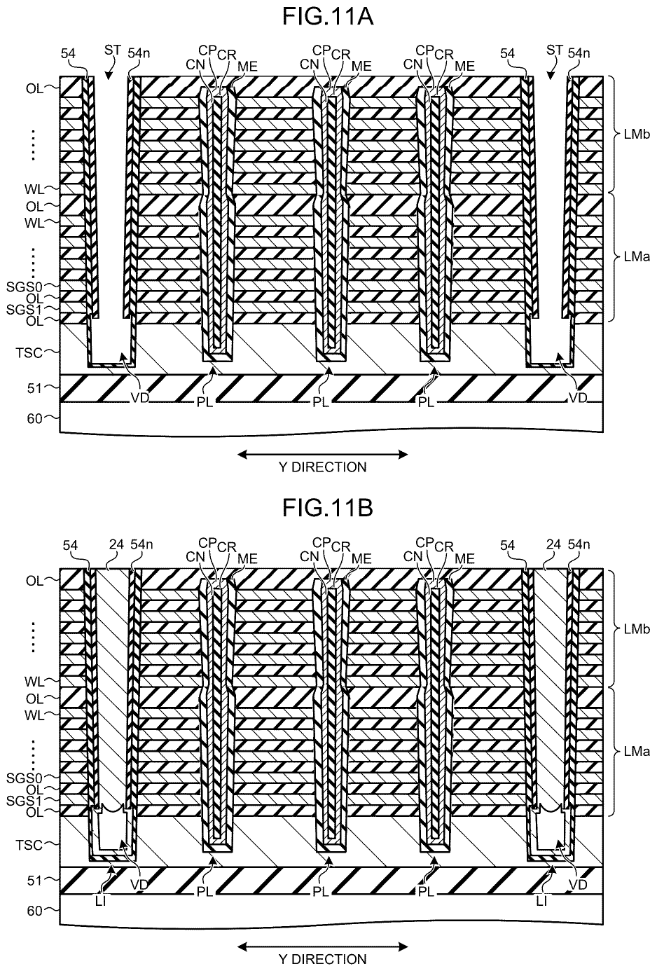

As illustrated in FIG. 11A, the insulating layer 54 exposed at the lower end of the insulating layer 54n is removed by wet etching or the like while maintaining a selectivity etching ratio with respect to the insulating layer 54n, and the void portion VD is formed at the lower end of the slit ST. At this time, the wet etching conditions and the like are adjusted so that the side walls and the bottom surface of the void portion VD are covered with the insulating layer 54 without completely removing the insulating layer 54 in a portion of the void portion VD.

When the insulating layer 54 is a silicon oxide layer and the insulating layer 54n is a silicon nitride layer, dilute hydrogen fluoride (DHF) or the like can be used as the wet etching solution.

As described above, since the thickness of the upper surface of the insulating layer 54 on the bottom surface of the slit ST is adjusted so as to be positioned below the height position of the word line WL of the lowermost layer of the subsequent stacked body LMa, the void portion VD is also positioned below the height position of the word line WL of the lowermost layer.

As illustrated in FIG. 11B, a tungsten layer or the like is filled in the slit ST to form the conductive layer 24. At this time, a film-forming condition with low coverage is used so that the void portion VD at the lower end of the slit ST is not filled.

Thus, the plate-like contact LI is formed.

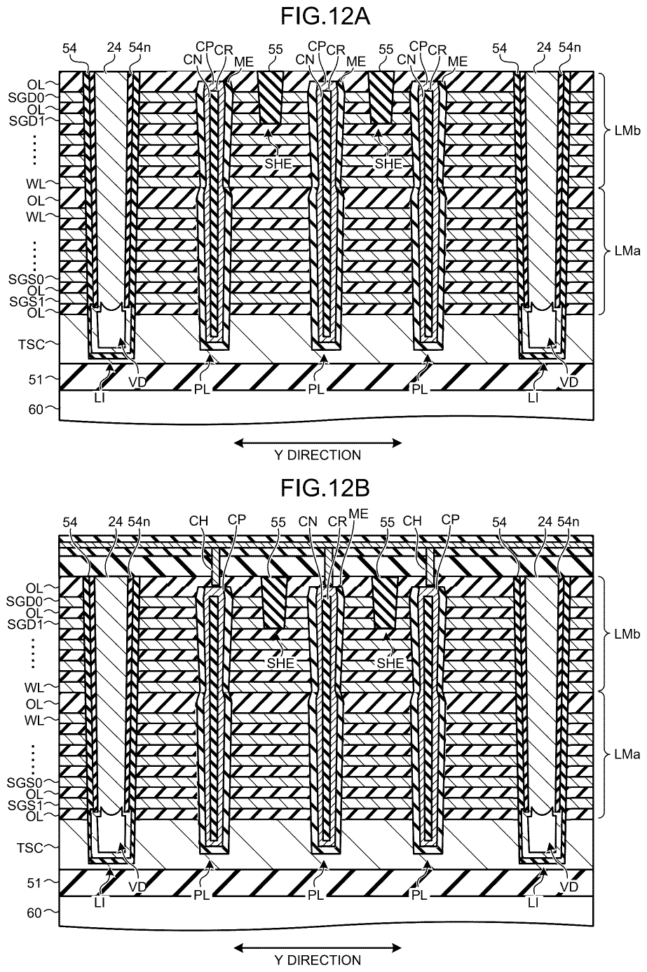

As illustrated in FIG. 12A, the separation layer SHE is formed on the upper layer side of the stacked body LM. More specifically, a groove penetrating one or a plurality of conductive layers including the uppermost conductive layer of the stacked body LMb is formed, and the insulating layer 56 is filled in the groove, thereby forming the separation layer SHE that partitions the conductive layers on the uppermost layer side of the stacked body LM into the pattern of the select gate line SGD.

In addition, although not illustrated, from the upper side of the stepped region SR, a plurality of contacts CC reaching the word lines WL and the select gate lines SGD and SGS constituting the respective steps of the stepped structure of the stepped region SR are formed.

As illustrated in FIG. 12B, after the insulating layer 52 covering the stacked body LM is formed, a plug CH penetrating the uppermost insulating layer OL and the insulating layer 52 of the stacked body LM and connected to the cap layer CP at the upper end of the pillar PL is formed. In addition, the insulating layer 53 covering the insulating layer 52 is formed, and the bit line BL to which each plug CH is connected is formed in the insulating layer 53.

For example, the plug CH and the bit line BL, and the like may be collectively formed by using a dual damascene method or the like.

In addition, although not illustrated, the peripheral circuit CBA is formed on the semiconductor substrate SB separate from the support substrate SS on which the stacked body LM is formed, and is covered with the insulating layer 40. In the insulating layer 40, a contact, a via, a wiring, or the like that leads the peripheral circuit CBA to the surface of the insulating layer 40 is formed and connected to an electrode pad or the like formed on the upper surface of the insulating layer 40.

In addition, the support substrate SS and the semiconductor substrate SB are bonded to each other by the insulating layers 50 and 40 which the support substrate SS and the semiconductor substrate SB have, respectively, and the electrode pads in the insulating layers 50 and 40 are connected. These insulating layers 50 and 40 can be joined by being activated in advance by, for example, plasma treatment or the like. In addition, by performing annealing after the insulating layers 54 and 40 are bonded, the electrode pads in the insulating layers 50 and 40 can be connected by Cu—Cu bonding or the like.

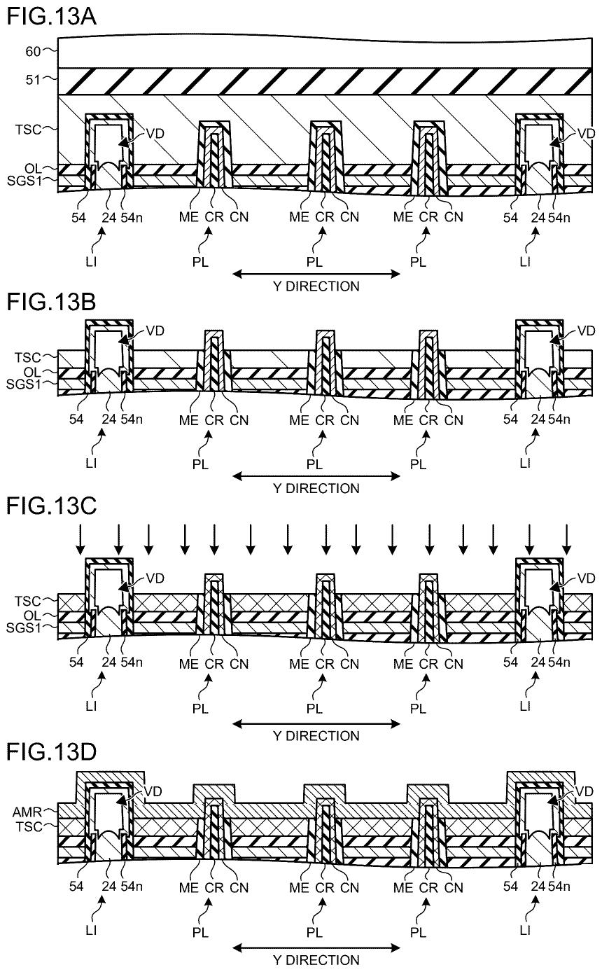

As illustrated in FIG. 13A, thereafter, various types of processing are performed from the side of the support substrate SS that is bonded in the vertical direction inverted on the semiconductor substrate SB. Therefore, in the following drawings, a state is illustrated in which various types of processing are performed from the upper ends side of the pillar PL and the plate-like contact LI with the portion of the pillar PL and the plate-like contact LI protruding to the semiconductor layer TSC as the upper end.

In the following drawings, only the upper ends of the pillars PL and the plate-like contacts LI are illustrated.

As illustrated in FIG. 13B, the support substrate SS is removed by cleaving the interface between the insulating layer 51 and the support substrate SS. Furthermore, the insulating layer 51 in the memory region MR in which the pillars PL and the like are formed is removed, and the semiconductor layer TSC is further removed with a predetermined layer thickness left. As a result, in the memory region MR, the upper ends of the pillars PL and the plate-like contacts LI penetrate the thinned semiconductor layer TSC and protrude upward.

In addition, the memory layer ME is removed from the portion of the pillar PL protruding above the semiconductor layer TSC. As a result, the upper end of the channel layer CN of the pillar PL is exposed above the semiconductor layer TSC. At this time, the insulating layer 54 of the plate-like contact LI can also be partially removed. However, since the insulating layer 54 is thicker than the memory layer ME, the entire insulating layer is not removed. When the insulating layer 54 is formed by the process of FIG. 9A described above, a stopper layer such as a silicon nitride layer may be formed in the insulating layer 54 separately from the insulating layer 54n to protect the inner insulating layer 54.

As illustrated in FIG. 13C, the semiconductor layer TSC is sequentially subjected to an ion implantation such as phosphorus, for example, to dope the semiconductor layer TSC with N-type impurities. At this time, the upper end of the channel layer CN may also be doped with impurities. By being doped with impurities such as phosphorus, the entire semiconductor layer TSC and at least the upper end of the channel layer CN become an amorphous semiconductor layer such as an amorphous silicon layer.

As illustrated in FIG. 13D, a semiconductor layer AMR covering the semiconductor layer TSC is formed. The semiconductor layer AMR is an amorphous semiconductor layer such as an amorphous silicon layer, and is formed in order to absorb laser light and use the laser light as a heat generation source at the time of subsequent annealing with laser light, and is a layer to be the source line SLa later.

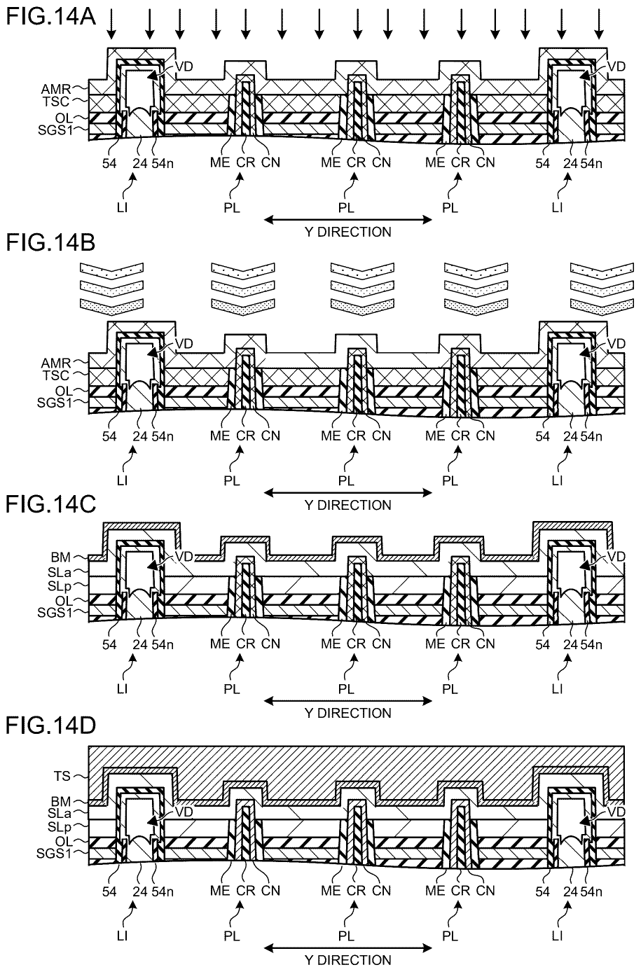

As illustrated in FIG. 14A, the semiconductor layer AMR and the upper end of the channel layer CN of the pillar PL are doped with impurities such as arsenic.

As illustrated in FIG. 14B, the semiconductor layer AMR and the upper end of the channel layer CN of the pillar PL are irradiated with laser light. As the laser light to be emitted, for example, laser light having a wavelength of 540 nm such as a green laser can be used.

At this time, the amorphous semiconductor layer such as the semiconductor layer AMR absorbs the laser light and functions as a heat source. As a result, the semiconductor layer AMR is heated by the laser light, and the heat of the semiconductor layer AMR is transferred to the semiconductor layer TSC, so that the semiconductor layer TSC can be annealed. As described above, when the laser light having a wavelength of 540 nm is used, the semiconductor layer TSC can be heated to, for example, about 1100° C.

By annealing using the heat of the laser light like this, the semiconductor layer TSC amorphized by doping of impurities is poly-crystallized, and the N-type impurities doped in the semiconductor layer TSC can be activated. In addition, the heat of the semiconductor layer AMR is also transmitted to the upper end of the channel layer CN of the pillar PL, and the amorphized channel layer CN and the originally amorphous semiconductor layer AMR are also poly-crystallized.

As described above, the source lines SLp and SLa, which are N-doped polysilicon layers and the like, are formed from the semiconductor layers TSC and AMR, respectively.

As illustrated in FIG. 14C, the barrier metal layer BM covering the source line SLa is formed.

As illustrated in FIG. 14D, a metal layer TS covering the barrier metal layer BM is formed.

Thereafter, the insulating layer 60 is formed on the metal layer TS, and the plug PG penetrating the insulating layer 60 is formed. Further, the electrode film EL connected to the plug PG in the insulating layer 60 is formed, and the insulating layer 70 covering the electrode film EL is formed. Further, an opening is provided in the insulating layer 70 to expose a part of the electrode film EL, thereby forming the pad region PD.

As described above, the semiconductor memory device 1 according to the embodiment is manufactured.

### Overview

A semiconductor memory device such as a three-dimensional nonvolatile memory may be manufactured by forming a peripheral circuit including a transistor and the like and a stacked body including a word line, a pillar PL, and the like on separate substrates and bonding these substrates.

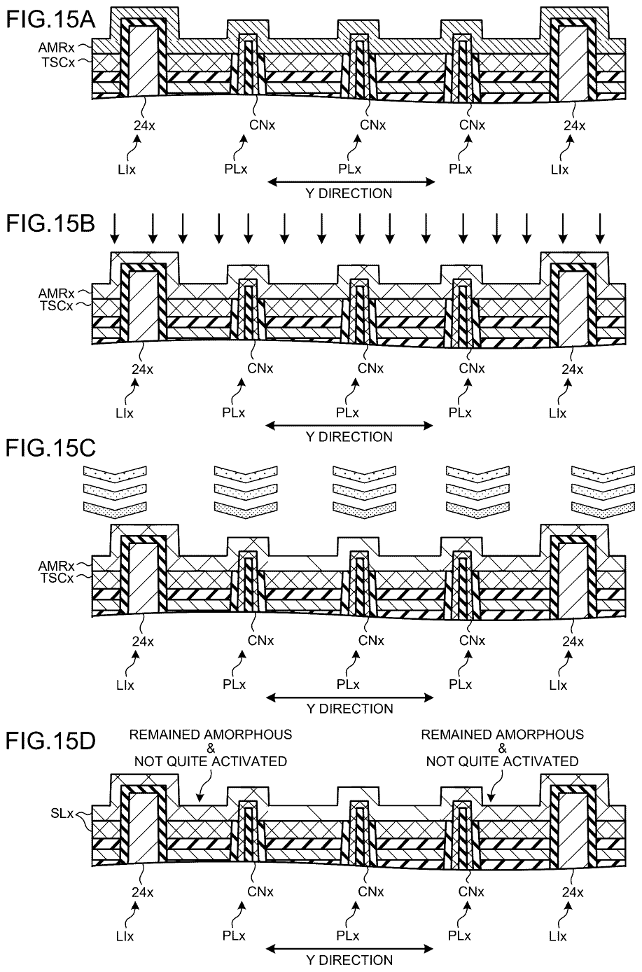

In addition, the source line connected to the pillar may be formed from the back surface side of the support substrate that supports the stacked body or the like after the substrates are bonded to each other, and at this time, the source line is doped with N-type impurities or the like and activated by annealing using the laser light. The state at this time is illustrated in FIGS. 15A to 15D.

FIGS. 15A to 15D are diagrams illustrating a method of forming a source line of a semiconductor memory device according to a comparative example.

The state of the semiconductor memory device of the comparative example illustrated in FIG. 15A corresponds to the state of FIG. 13D of the above-described embodiment.

As illustrated in FIG. 15A, a pillar PLx having a channel layer CNx whose upper end protrudes above a thinned semiconductor layer TSCx, a plate-like contact LIx having a conductive layer 24x whose upper end protrudes above the thinned semiconductor layer TSCx, and a semiconductor layer AMRx covering these are formed on the upper surface of the semiconductor substrate with the peripheral circuit and the stacked body bonded.

Note that the plate-like contact LIx of the comparative example does not have the above-described void portion VD at the upper end, and the entire inside of the plate-like contact LIx is filled with the conductive layer 24x.

As illustrated in FIG. 15B, the semiconductor layer TSCx and the upper end of the channel layer CNx of the pillar PLx are doped with impurities such as phosphorus. As a result, the entire semiconductor layer TSCx and the upper end of the channel layer CNx are amorphized.

As illustrated in FIG. 15C, the semiconductor layer AMRx and the upper end of the channel layer CNx of the pillar PLx are doped with impurities such as arsenic, and then irradiated with laser light.

As a result, the semiconductor layer AMRx is heated by the laser light, and the heat of the semiconductor layer AMRx is further transferred to the semiconductor layer TSCx and the upper end of the channel layer CNx of the pillar PLx, and the semiconductor layers AMRx and TSCx and the channel layer CNx are annealed. Therefore, the semiconductor layers AMRx and TSCx are poly-crystallized, and impurities in the semiconductor layers AMRx and TSCx are activated.

However, as illustrated in FIG. 15D, in the semiconductor memory device of the comparative example, in some cases, impurities in the source line SLx is not sufficiently activated around the pillar PLx adjacent to the plate-like contact LIx.

This is because the heat by the laser light is dissipated to the conductive layer 24x included in the plate-like contact LIx. As a result, in the vicinity of the plate-like contact LIx, the temperature of the semiconductor layers AMRx, TSCx, and the like decreases, and it is considered that impurities cannot be activated.

Therefore, the heat of the laser light is prevented from being dissipated to the conductive layer 24x. The thermal conductivity of the upper end of the plate-like contact LIx is lower than that in the case where the conductive layer 24x is present.

According to the semiconductor memory device 1 of the embodiment, the plate-like contact LI includes the plate-like contact LI that extends in the stacked body LM in the direction along the X direction and the stacking direction of the stacked body LM at the position adjacent to the pillar PL and includes the conductive layer 24 having the upper end protruding from the stacked body LM, and the source line SLa that is disposed above the stacked body LM, covers the upper end of the channel layer CN of the pillar PL and the upper end of the plate-like contact LI, and contains a semiconductor as a main component, and the plate-like contact LI has the void portion VD at the upper end thereof.

The void portion VD included in the upper end of the plate-like contact LI functions as a favorable heat insulating member. This prevents heat generated by the laser light from being dissipated to the conductive layer 24 of the plate-like contact LI. Therefore, the source lines SLp and SPa can be sufficiently heated to activate the impurities in the source lines SLp and SPa.

According to the semiconductor memory device 1 of the embodiment, the plate-like contact LI covers the side walls and the upper surface of the plate-like contact LI, and includes the insulating layer 54 that separates the conductive layer 24 and the source line SLa. This prevents conduction between the conductive layer 24 of the plate-like contact LI and the source line SLa.

According to the semiconductor memory device 1 of the embodiment, the plate-like contact LI further includes the insulating layer 54n that covers the side walls of the conductive layer 24 inside the insulating layer 54 and contains a material different from the insulating layer 54. Accordingly, when the insulating layer 54 is removed by etching to form the void portion VD at the upper end of the plate-like contact LI, the insulating layer 54n can protect the side walls of the slit SL by taking a selectivity etching ratio with respect to the insulating layer 54n.

According to the semiconductor memory device 1 of the embodiment, the void portion VD of the plate-like contact LI is located above the select gate line SGS1 of the uppermost layer of the stacked body LM. As a result, the strength of the plate-like contact LI can be sufficiently maintained, and chipping can be suppressed from occurring when the semiconductor memory device 1 is singulated. In addition, even if the void portion VD of the plate-like contact LI is extended to the height position of the select gate line SGS1 or less, the select gate line SGS1 itself has a heat dissipation property and thus does not contribute to the suppression of the heat dissipation of the laser light.

### First Modification

In the above-described embodiment, the insulating layer 54 on the bottom surface of the slit ST is thickened and removed by wet etching or the like to form the void portion VD at the lower end of the plate-like contact LI. However, the method for forming the void portion in the plate-like contact is not limited thereto.

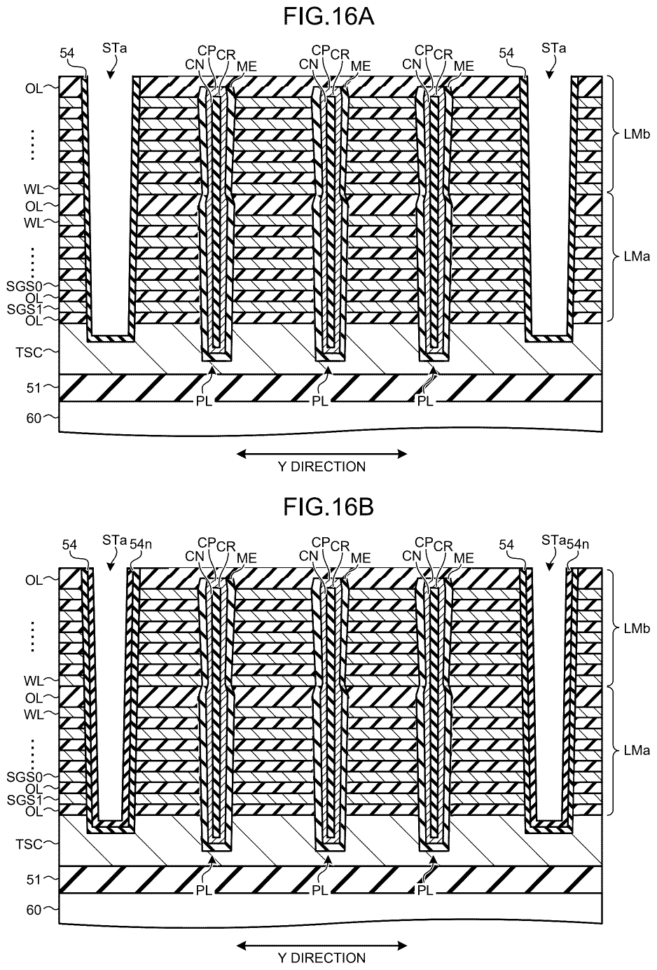

Hereinafter, in the first modification of the embodiment, another method of forming the void portion in the plate-like contact will be described with reference to FIGS. 16A to 19D.

FIGS. 16A to 19D are diagrams illustrating a part of the procedure of a method for manufacturing a semiconductor memory device according to the first modification of the embodiment. More specifically, FIGS. 16A to 19D illustrate a cross section along the Y direction of a region to be the memory region later, similarly to FIGS. 3A to 14D of the above-described embodiment.

Note that in FIGS. 16A to 19D, the same reference numerals are given to the same configurations as those of the above-described embodiment, and the description thereof may be omitted. In addition, FIGS. 16A to 19D mainly illustrate a method of forming a void portion VDa in a plate-like contact LIa.

FIG. 16A illustrates a state after the replacement of the insulating layers NL is completed and the stacked body LM including the plurality of word lines WL and the like is formed. That is, FIG. 16A corresponds to FIG. 9A of the above-described embodiment.

As illustrated in FIG. 16A, at the time of replacement of the stacked body LM, a slit STa of the first modification is formed such that the reaching depth in the semiconductor layer TSC is shallower than the slit ST of the above-described embodiment. However, the reaching depth of the slit STa is preferably equal to or larger than the thickness of the semiconductor layer TSC to be finally left as the source line SLp in the semiconductor memory device of the first modification.

Further, after the replacement of the stacked body LM, the insulating layer 54 covering the side walls and the bottom surface of the slit STa is formed. At this time, the insulating layer 54 is formed to have a layer thickness substantially equal to that of the insulating layer 54 to be finally included in the semiconductor memory device of the first modification.

As illustrated in FIG. 16B, the insulating layer 54n covering the side walls and the bottom surface of the slit ST is formed via the insulating layer 54.

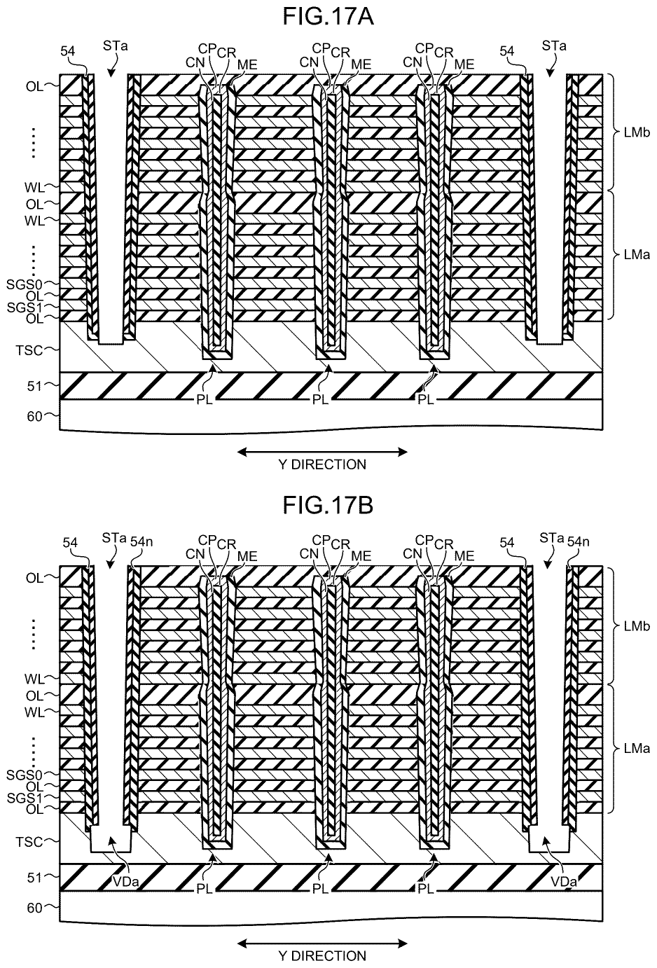

As illustrated in FIG. 17A, the insulating layers 54n and 54 on the bottom surface of the slit ST are removed by dry etching or the like to expose the semiconductor layer TSC from the bottom surface of the slit ST.

As illustrated in FIG. 17B, the semiconductor layer TSC exposed at the lower end of the insulating layer 54n is removed by wet etching or the like while maintaining a selectivity etching ratio with respect to the insulating layer 54n, and the void portion VDa is formed at the lower end of the slit STa. The insulating layer 54n is, for example, a silicon nitride layer or the like, and the semiconductor layer TSC is, for example, a silicon layer or the like, and thus, it is possible to maintain etching selectivity between these different members.

As described above, since the original reaching depth of the slit STa is shallow, the height position of the upper end of the void portion VDa at the lower end of the slit STa does not necessarily reach the lower surface of the stacked body LM, and the void portion VDa may be smaller in size than, for example, the void portion VD of the above-described embodiment.

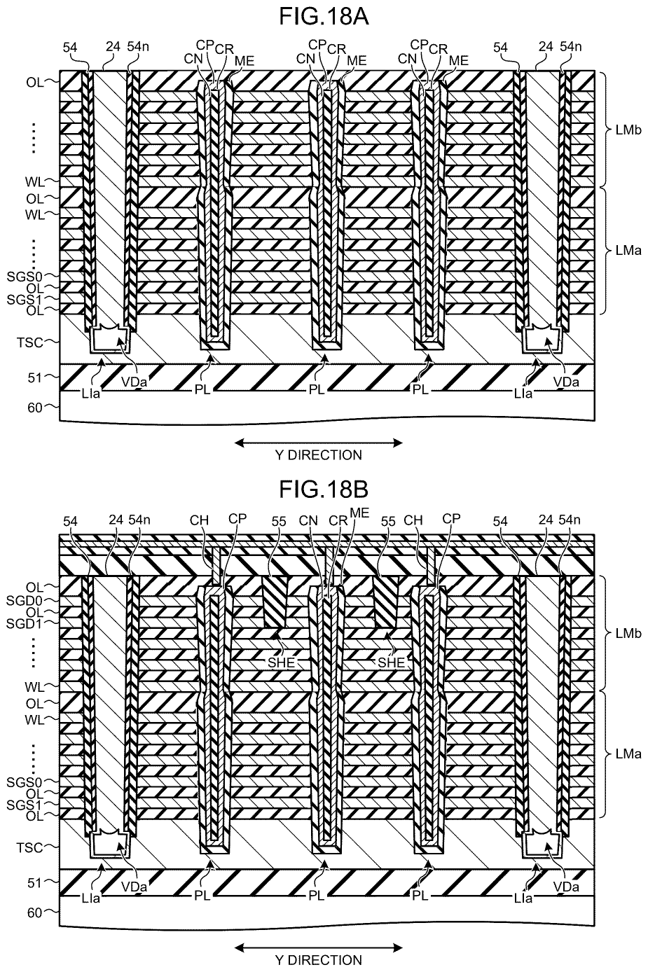

As illustrated in FIG. 18A, a tungsten layer or the like is filled in the slit STa to form the conductive layer 24. At this time, a film-forming condition with low coverage is used so that the void portion VDa at the lower end of the slit STa is not filled.

Thus, the plate-like contact LIa of the first modification is formed. However, at this time, the conductive layer 24 covering the void portion VDa at the lower end of the plate-like contact LIa is not covered with the insulating layer 54 or the like, and is in direct contact with the semiconductor layer TSC.

As illustrated in FIG. 18B, the separation layer SHE is formed on the upper layer side of the stacked body LM, the insulating layers 52 and 53 covering the stacked body LM are formed, the plug CH connected to the cap layer CP is formed, and the bit line BL connected to the plug CH is formed.

In addition, the support substrate SS and the semiconductor substrate SB on which the peripheral circuit CBA is formed are bonded.

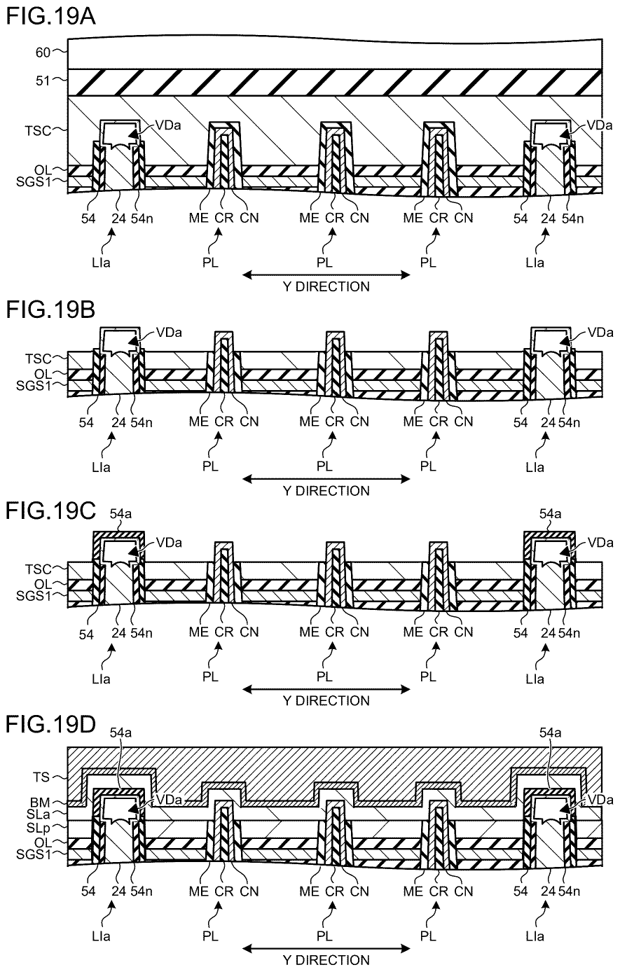

As illustrated in FIG. 19A, thereafter, various types of processing are performed from the side of the support substrate SS that is bonded on the semiconductor substrate SB in the vertical direction inverted. In FIGS. 19A to 19D, only the upper ends of the pillars PL and the plate-like contacts LIa are illustrated.

As illustrated in FIG. 19B, the support substrate SS and the insulating layer 51 are removed, the semiconductor layer TSC is removed with a predetermined layer thickness left, and the memory layer ME is removed from the upper end of the pillar PL protruding above the semiconductor layer TSC.

At this time, since the upper end of the plate-like contact LIa protruding upward above the semiconductor layer TSC is in a state where the void portion VDa is covered with the conductive layer 24 such as a tungsten layer, the upper end of the plate-like contact LIa is hardly affected by the removal processing of the memory layer ME from the upper end of the pillar PL. In addition, as described above, since the depth of the slit STa is set to be equal to or larger than the thickness of the semiconductor layer TSC after the thickness reduction, the side walls of the plate-like contact LIa are covered with the insulating layer 54 up to a portion penetrating the semiconductor layer TSC.

As illustrated in FIG. 19C, an insulating layer 54a such as a silicon oxide layer covering the conductive layer 24 exposed to cover the void portion VDa is formed at the upper end of the plate-like contact LIa. Then, this suppresses conduction between the conductive layer 24 of the plate-like contact LIa and the semiconductor layer AMR when the semiconductor layer AMR covering the upper ends of the plate-like contact LIa and the pillars PL is formed.

However, the insulating layer 54a may be formed before the process of removing the memory layer ME from the upper end of the pillar PL described above. In this case, it is preferable to form the insulating layer 54a thick so that the insulating layer 54a is not completely removed when the memory layer ME is removed.

Thereafter, processing similar to the processing of FIGS. 13C to 14D of the above-described embodiment is performed. That is, the semiconductor layer TSC is doped with impurities such as phosphorus to form the semiconductor layer AMR covering the upper ends of the plate-like contact LIa and the pillar PL, the semiconductor layer AMR and the upper ends of the pillars PL are doped with impurities such as arsenic, and the entire upper surface of the stacked body LM is irradiated with laser light.

As illustrated in FIG. 19D, thereafter, the barrier metal layer BM covering the source line SLa is formed, and the metal layer TS covering the barrier metal layer BM is formed.

In addition, the same processing as that of the above-described embodiment is continued thereafter.

As described above, the semiconductor memory device according to the first modification is manufactured.

According to the semiconductor memory device of the first modification, the same effects as those of the above-described embodiment are obtained.

### Second Modification

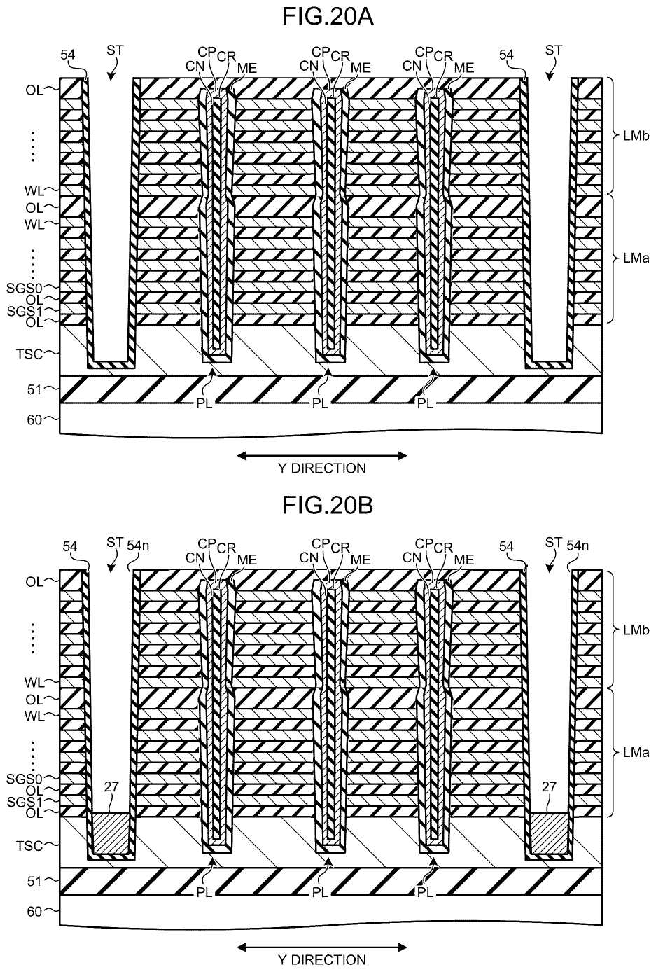

Next, a semiconductor memory device according to a second modification of the embodiment will be described with reference to FIGS. 20A to 22B. In the second modification of the embodiment, still another method of forming the void portion in the plate-like contact will be described.

FIGS. 20A to 22B are diagrams sequentially illustrating a part of the procedure of a method for manufacturing the semiconductor memory device according to the second modification of the embodiment. More specifically, FIGS. 20A to 22B illustrate a cross section along the Y direction of a region to be the memory region later, similarly to FIGS. 3A to 14D of the above-described embodiment.

In FIGS. 20A to 22B, the same reference numerals are given to the same configurations as those of the embodiment, and the description thereof may be omitted. In addition, FIGS. 20A to 22B mainly illustrate a method of forming a void portion VDb in a plate-like contact LIb.

FIG. 20A illustrates a state after the replacement of the insulating layers NL is completed and the stacked body LM including the plurality of word lines WL and the like is formed. That is, FIG. 20A corresponds to FIG. 9A of the above-described embodiment.

As illustrated in FIG. 20A, at the time of replacement of the stacked body LM, a slit ST of the second modification is formed such that the reaching depth in the semiconductor layer TSC is substantially equal to the slit ST of the above-described embodiment.

Further, after the replacement of the stacked body LM, the insulating layer 54 covering the side walls and the bottom surface of the slit ST is formed. At this time, the insulating layer 54 is formed to have a layer thickness substantially equal to that of the insulating layer 54 to be finally included in the semiconductor memory device of the second modification.

As illustrated in FIG. 20B, a sacrificial layer 27 such as an amorphous silicon layer is formed on the bottom surface of the slit ST via the insulating layer 54.

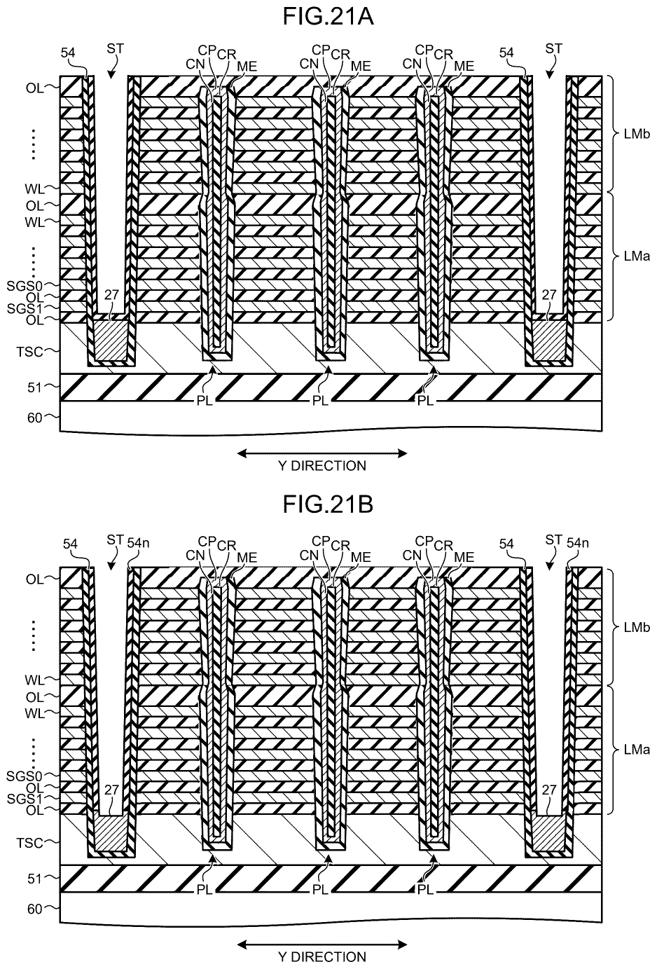

As illustrated in FIG. 21A, the insulating layer 54n covering the side walls and the bottom surface of the slit ST is formed via the insulating layer 54 and the sacrificial layer 27.

As illustrated in FIG. 21B, the insulating layer 54n on the bottom surface of the slit ST is removed by dry etching or the like to partially expose the sacrificial layer 27.

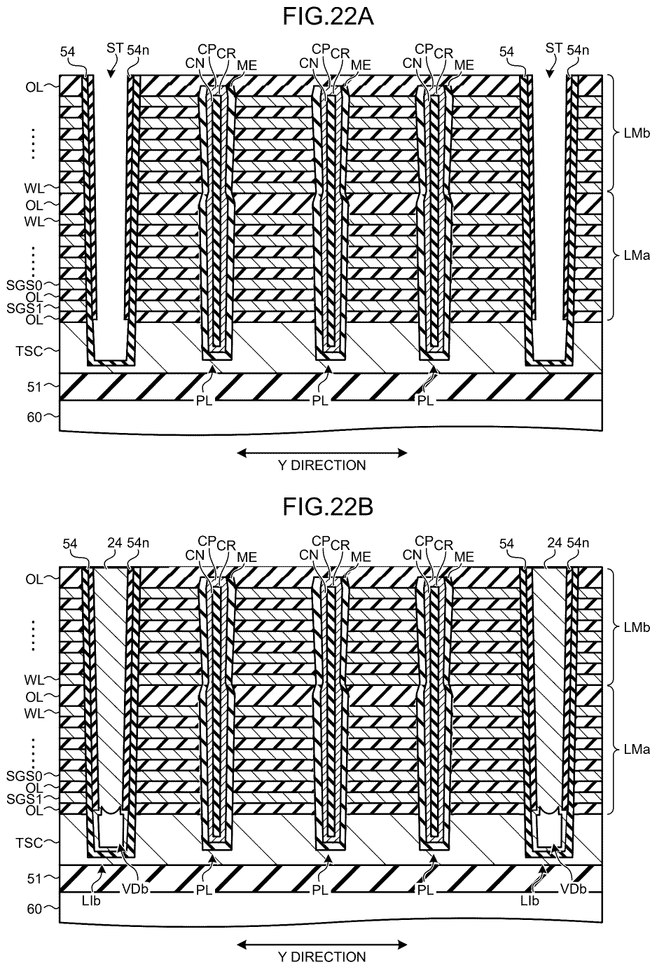

As illustrated in FIG. 22A, the sacrificial layer 27 exposed at the lower end of the insulating layer 54n is removed by wet etching or the like while maintaining a selectivity etching ratio with respect to the insulating layer 54n, and the void portion VDb is formed at the lower end of the slit ST. The insulating layer 54n is, for example, a silicon nitride layer or the like, and the sacrificial layer 27 is, for example, an amorphous silicon layer or the like, and thus, it is possible to maintain etching selectivity between these different members.

As illustrated in FIG. 22B, a tungsten layer or the like is filled in the slit ST to form the conductive layer 24. At this time, a film-forming condition with low coverage is used so that the void portion VDb at the lower end of the slit ST is not filled.

Thus, the plate-like contact LIb of the second modification is formed.

Thereafter, the processing of FIG. 12A and subsequent drawings of the above-described embodiment is performed.

As described above, the semiconductor memory device according to the second modification is manufactured.

According to the semiconductor memory device of the second modification, the same effects as those of the above-described embodiment are obtained.

### Third Modification

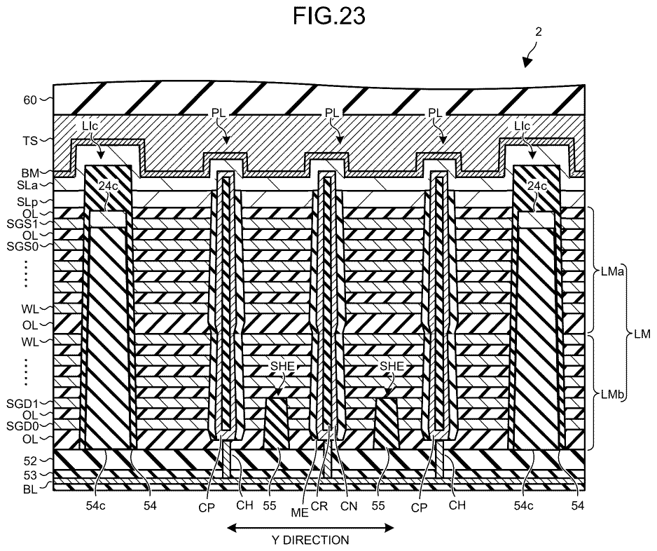

Next, a semiconductor memory device 2 according to a third modification of the embodiment will be described with reference to FIGS. 23 to 25B. The third modification is different from the above-described embodiment in that the plate-like contact does not have a void portion. In the following drawings, the same reference numerals are given to the same configurations as those of the above-described embodiment, and the description thereof may be omitted.

FIG. 23 is a cross-sectional view illustrating a schematic configuration example of the semiconductor memory device 2 according to the third modification of the embodiment. More specifically, FIG. 23 is a cross-sectional view along the Y direction of the memory region MR of the semiconductor memory device 2.

As illustrated in FIG. 23, the semiconductor memory device 2 of the third modification includes a plate-like contact LIc instead of the plate-like contact LI of the above-described embodiment. The plate-like contact LIc includes an insulating layer 54 covering the side walls and the upper surface of the plate-like contact LIc, an insulating layer 54c filled in the plate-like contact LIc, and a conductive layer 24c interposed between the insulating layers 54 and 54c covering the upper surface of the plate-like contact LIc and disposed at the upper end of the plate-like contact LIc.

More specifically, the insulating layer 54 has a layer thickness thicker in a portion covering the upper surface of the plate-like contact LIc than in a portion covering the side walls of the plate-like contact LIc. In addition, the conductive layer 24c is disposed at a height position of the select gate line SGS1 of the uppermost layer of the stacked body LM at a position between the insulating layer 54 covering the upper surface of the plate-like contact LIc and the insulating layer 54c. The thickness of the conductive layer 24c is substantially the same as the thickness of the select gate line SGS1.

Note that the insulating layers 54 and 54c are silicon oxide layers and the like, and the conductive layer 24c is a tungsten layer and the like.

As described above, the plate-like contact LIc of the third modification includes the thin conductive layer 24c at the upper end of the plate-like contact LIc. That is, the volume of the conductive layer 24c is smaller than, for example, the conductive layer 24 included in the plate-like contact LI of the above-described embodiment. Therefore, the heat of the laser light is suppressed from being dissipated to the conductive layer 24c, and the conductive layer 24c has a role of reflecting the laser light exclusively. The laser light reflected by the conductive layer 24c returns to the semiconductor layer AMR during laser irradiation, and promotes further heat generation of the semiconductor layer AMR.

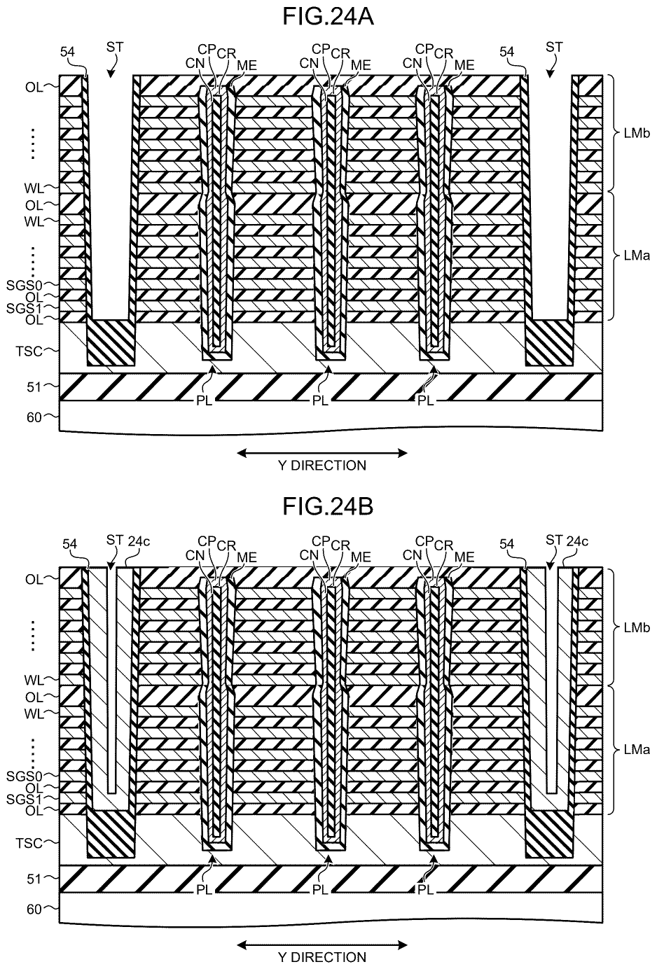

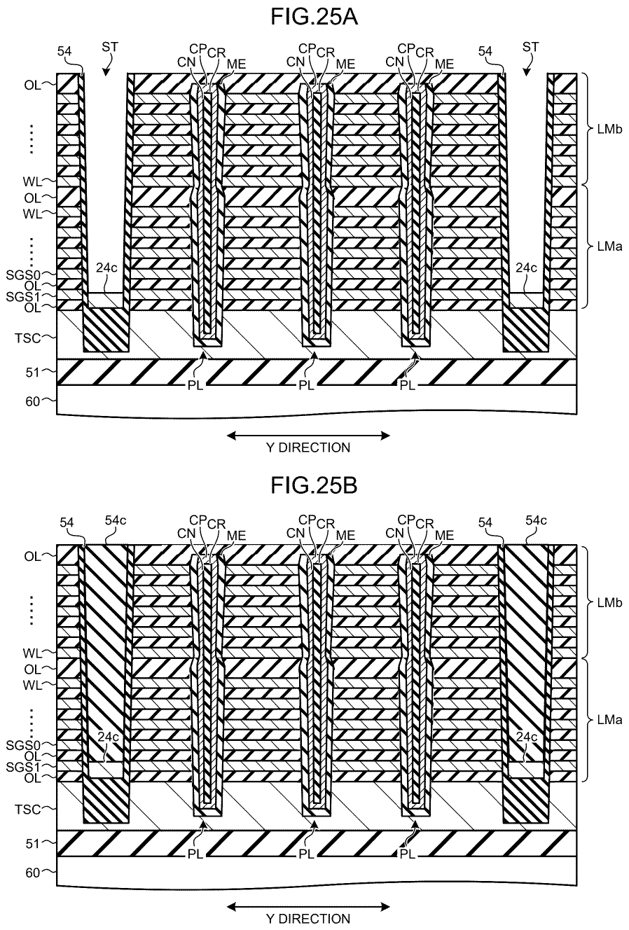

FIGS. 24A to 25B illustrate a method of forming the above-described plate-like contact LIc.

FIGS. 24A to 25B are diagrams sequentially illustrating a part of the procedure of a method for manufacturing the semiconductor memory device 2 according to the third modification of the embodiment. More specifically, FIGS. 24A to 25B illustrate a cross section along the Y direction of a region to be the memory region later, similarly to FIGS. 3A to 14D of the above-described embodiment.

Note that FIGS. 24A to 25B mainly illustrate a method of forming the void portion VDb in the plate-like contact LIb.

FIG. 24A illustrates a state after the replacement of the insulating layers NL is completed and the stacked body LM including the plurality of word lines WL and the like is formed. That is, FIG. 24A corresponds to FIG. 9A of the above-described embodiment.

As illustrated in FIG. 24A, at the time of replacement of the stacked body LM, a slit ST of the third modification is formed such that the reaching depth in the semiconductor layer TSC is substantially equal to the slit ST of the above-described embodiment.

Further, after the replacement of the stacked body LM, the insulating layer 54 covering the side walls and the bottom surface of the slit ST is formed. At this time, in the insulating layer 54, the portion covering the bottom surface of the slit ST is thickened by the same method as in the above-described embodiment.

As illustrated in FIG. 24B, the conductive layer 24 covering the side walls and the bottom surface of the slit ST is formed via the insulating layer 54.

As illustrated in FIG. 25A, the conductive layer 24 covering the side walls of the slit ST is removed to form the conductive layer 24c remaining on the bottom surface of the slit ST. Such processing can be performed by, for example, dry etching using isotropic conditions.

As illustrated in FIG. 25B, a void generated above the slit ST is filled with the insulating layer 54c.

Thus, the plate-like contact LIc of the third modification is formed.

Thereafter, the processing of FIG. 12A and subsequent drawings of the above-described embodiment is performed.

As described above, the semiconductor memory device 2 according to the third modification is manufactured.

According to the semiconductor memory device 2 of the third modification, the plate-like contact LIc includes the plate-like contact LIc that extends in the stacked body LM in the direction along the X direction and the stacking direction of the stacked body LM at the position adjacent to the pillar PL and includes the conductive layer 24 having the upper end protruding from the stacked body LM, and the source line SLa that is disposed above the stacked body LM, covers the upper end of the channel layer CN of the pillar PL and the upper end of the plate-like contact LIc, and contains a semiconductor as a main component, and the plate-like contact LIc has the conductive layer 24c at a height position of the select gate line SGS1 of the uppermost layer of the stacked body LM.

As a result, it is possible to suppress the heat of the laser light from being dissipated to the conductive layer 24c. In addition, the conductive layer 24c can reflect the laser light to the semiconductor layer AMR to promote heat generation of the semiconductor layer AMR.

According to the semiconductor memory device 2 of the third modification, other effects similar to those of the above-described embodiment are obtained.

### Other Modifications

In the above-described embodiment and the first to third modifications, the semiconductor memory device includes the stacked body LM having the two-tier structure in which the two stacked bodies LMa and LMb are stacked vertically. However, the configuration of the stacked body is not limited to two tiers, and may be one tier or three tiers or more.

Further, in the above-described embodiment and the first to third modifications, the stepped regions SR are arranged at both ends in the X direction of the stacked body LM. However, the stepped region may be disposed at the center in the X direction of the stacked body, and the memory regions MR may be disposed at both ends in the X direction.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a stacked body in which a plurality of first conductive layers and a plurality of first insulating layers are alternately stacked one by one;
a pillar extending in the stacked body in a stacking direction of the stacked body and including a semiconductor layer having an upper end protruding from the stacked body;
a plate-like portion extending in the stacked body in the staking direction and a first direction intersecting the stacking direction at a position adjacent to the pillar, the plate-like portion including a second conductive layer having an upper end protruding from the stacked body; and
a first layer that is disposed above the stacked body, covers the upper end of the semiconductor layer and an upper end of the plate-like portion, and contains a semiconductor as a main component,
wherein the plate-like portion includes a void portion in the upper end thereof.

2. The semiconductor memory device according to claim 1, wherein
the plate-like portion includes a second insulating layer covering side walls and an upper surface of the plate-like portion and separating the second conductive layer and the first layer, and
the semiconductor layer is connected to the first layer.

3. The semiconductor memory device according to claim 2, wherein
the plate-like portion further includes a third insulating layer that covers side walls of the second conductive layer inside the second insulating layer and includes a material different from a material of the second insulating layer.

4. The semiconductor memory device according to claim 2, wherein
the first layer is a polycrystalline semiconductor layer containing an impurity of a first conductivity type.

5. The semiconductor memory device according to claim 4, wherein
the impurity is also contained in the upper end of the semiconductor layer.

6. The semiconductor memory device according to claim 4, further comprising
a second layer interposed between the first layer and the stacked body and containing a semiconductor as a main component,
wherein the impurity is also contained in the second layer.

7. The semiconductor memory device according to claim 4, wherein
the impurity includes at least one selected from the group of arsenic and phosphorus.

8. The semiconductor memory device according to claim 1, wherein
the void portion is located above an uppermost first conductive layer of the plurality of first conductive layers.

9. The semiconductor memory device according to claim 1, wherein
the void portion is included in the second conductive layer.

10. A semiconductor memory device comprising:
a stacked body in which a plurality of first conductive layers and a plurality of first insulating layers are alternately stacked one by one;
a pillar extending in the stacked body in a stacking direction of the stacked body and including a semiconductor layer having an upper end protruding from the stacked body;
a plate-like portion extending in the stacked body in the staking direction and a first direction intersecting the stacking direction at a position adjacent to the pillar, the plate-like portion having an upper end protruding from the stacked body; and
a first layer that is disposed above the stacked body, covers the upper end of the semiconductor layer and the upper end of the plate-like portion, and contains a semiconductor as a main component,
wherein the plate-like portion includes a second conductive layer at a height position of an uppermost first conductive layer of the stacked body of the plurality of first conductive layer.

11. A method of manufacturing a semiconductor memory device comprising:
forming a stacked body in which a plurality of first conductive layers and a plurality of first insulating layers are alternately stacked one by one, a pillar extending in the stacked body in a stacking direction of the stacked body and including a semiconductor layer having an upper end protruding from the stacked body, and a plate-like portion extending in the stacked body in the staking direction and a first direction intersecting the stacking direction at a position adjacent to the pillar, the plate-like portion including a second conductive layer having an upper end protruding from the stacked body;
forming a first layer that is disposed above the stacked body, covers the upper end of the semiconductor layer and an upper end of the plate-like portion, and contains a semiconductor as a main component; and
injecting an impurity of a first conductivity type into the first layer and emitting laser light on the entire stacked body including the first layer, wherein
the forming the plate-like portion includes:
forming a slit extending in the stacked body in the first direction and the stacking direction;
forming a second insulating layer covering side walls of the slit;
forming a third insulating layer covering the side walls of the slit via the second insulating layer;
forming a void portion at an upper end of the slit while protecting the side walls of the slit with the second and third insulating layers; and
forming the second conductive layer in the slit with the void portion left.

12. The method for manufacturing a semiconductor memory device according to claim 11, wherein
the forming the second conductive layer includes
filling the slit with the second conductive layer under a condition of low coverage to an extent that the void portion is not filled.

13. The method for manufacturing a semiconductor memory device according to claim 11, wherein
the forming the void portion includes:
forming the second insulating layer covering an upper surface together with the side walls of the slit and thickening a portion covering the upper surface; and
removing the second insulating layer of the thickened portion while protecting the second insulating layer covering the side walls of the slit with the third insulating layer.

14. The method for manufacturing a semiconductor memory device according to claim 11, wherein
the forming the void portion includes:
forming the second insulating layer covering an upper surface together with the side walls of the slit;
forming a sacrificial layer on the second insulating layer in a portion covering the upper surface of the slit; and
removing the sacrificial layer exposed at an upper end of the third insulating layer covering the side walls of the slit.

15. The method for manufacturing a semiconductor memory device according to claim 11, wherein
a second layer containing a semiconductor as a main component is formed on an upper surface of the stacked body,
the forming the slit includes
forming the slit that penetrates the stacked body in the stacking direction and reaches the inside of the second layer,
the forming the void portion includes
removing the second layer exposed from the upper end of the slit,
the forming the second conductive layer includes
covering side walls and an upper surface of the void portion with the second conductive layer while leaving the void portion,
the forming the plate-like portion includes
removing the second layer while leaving a predetermined layer thickness, and allowing the upper end of the plate-like portion including the void portion covered with the second conductive layer to protrude above the second layer together with the semiconductor layer, and
the forming the first layer includes:
covering, with a fourth conductive layer, the second conductive layer that covers the void portion; and
covering, with the first layer, the upper end of the plate-like portion covered with the fourth conductive layer.

16. The method for manufacturing a semiconductor memory device according to claim 11, wherein
the emitting the laser light includes
poly-crystallizing the first layer that became amorphous by injecting the impurity.

17. The method for manufacturing a semiconductor memory device according to claim 16, wherein
the impurity includes at least one selected from the group of arsenic and phosphorus.

18. The method for manufacturing a semiconductor memory device according to claim 11, wherein
the stacked body having the pillar is formed above a first substrate,
prior to forming the first layer,
a second substrate on which a peripheral circuit contributing to an electrical operation of the pillar is formed is prepared, and
the first substrate and the second substrate are bonded to remove the first substrate.
